(19) United States
(12) Patent Application Publication
(10) Pub. No.: US 2005/0221524 A1
(43) Pub. Date: Oct. 6, 2005

(54) Method for forming film pattern, method for manufacturing device, electro-optical apparatus, electronic apparatus, and method for manufacturing active matrix substrate

(75) Inventor: Toshimitsu Hirai, Chino-shi (JP)

Correspondence Address: SHINJYU GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/094,798

(22) Filed: Mar. 31, 2005

(30) Foreign Application Priority Data
Apr. 6, 2004 (JP) 2004-112065

(51) Int. Cl. H01L 21/00

(52) U.S. Cl. 438/30; 427/58

(57) ABSTRACT

A method for forming a film pattern by placing a functional fluid on a substrate, the method includes forming banks having a predetermined pattern on the substrate, providing a receiving film comprising a porous member, in a groove between the banks, and placing the functional fluid on the receiving film.

### BACKGROUND OF THE INVENTION

1. Field of the Invention

The present invention relates to a method for forming a film pattern, a method for manufacturing a device, an electro-optical apparatus, an electronic apparatus, and a method for manufacturing an active matrix substrate.

Priority is claimed on Japanese Patent Application No. 2004-112065, filed Apr. 6, 2004, the content of which is incorporated herein by reference.

2. Description of Related Art

For example, a photolithography method is used to manufacture devices such as electronic circuits or integrated circuits which have wiring. The photolithography method includes applying a photosensitive material called a resist to a substrate to which a conductive film has already been applied, forming a circuit pattern by irradiation and developing the circuit pattern, and etching the conductive film in accordance with a resist pattern to form a thin film wiring pattern. The photolithography method requires large-scale facilities such as a vacuum apparatus and complicated operations. Further, material use efficiency is only about several percent. Most of the materials used must be disposed of. Therefore, manufacturing costs are high.

In contrast, a method has been proposed which forms a wiring pattern on a substrate using a liquid ejecting method of ejecting a functional fluid in droplet form from a droplet ejecting head, that is, an ink jet method (see, for example, U.S. Pat. No. 5,132,248). With this method, a functional fluid in which fine conductive grains such as fine metal grains are dispersed is applied directly to a substrate to form a pattern. Subsequently, a thermal treatment or laser irradiation is carried out to convert the pattern into a conductive film pattern. This method eliminates the need for lithography to drastically simplify the process. The method also reduces the amounts of materials used.

When a film pattern constituting a device is formed on the basis of the liquid ejecting method, it is important to arrange droplets ejected from an ejection head at desired positions in a desired state in order to obtain favorable device characteristics.

The present invention was made in view of these circumstances. It is an object of the present invention to provide a method for forming a film pattern, a method for manufacturing a device, an electro-optical apparatus, an electronic apparatus, and a method for manufacturing an active matrix substrate wherein when a film pattern is formed on a substrate using a liquid ejecting method, droplets can be arranged at desired positions in a desired state.

### SUMMARY OF THE INVENTION

The present invention employs a configuration described below in order to accomplish the above object.

The present invention provides a method for forming a film pattern by placing a functional fluid on a substrate, the method including forming banks having a predetermined pattern on the substrate, providing a receiving film comprising a porous member, in a groove between the banks, and placing the functional fluid on the receiving film.

According to the present invention, the receiving film including the porous member is provided in the groove between the banks. Consequently, the functional fluid placed on the receiving film is absorbed by and favorably held in the receiving film. Therefore, the functional fluid can be appropriately placed in the groove between the grooves to form a film pattern with a desired shape. Further, even if part of the functional fluid splashes on a top surface of the banks when the functional fluid is placed in the groove, the receiving film can absorb the functional fluid to draw the functional fluid lying on the top surface of the banks, into the groove. This makes it possible to prevent residues of the functional fluid from being disadvantageously present on the top surface of the banks. It is thus possible to prevent the degradation of the device characteristics resulting from the residues.

In the method for forming a film pattern, the proving the receiving film includes placing a second functional fluid in the groove and executing a predetermined process on the second functional fluid placed in the groove to convert the second functional fluid into the receiving film.

According to the present invention, the second functional fluid is placed in the groove and is then subjected to the predetermined process. Consequently, the receiving film can be smoothly formed in the groove.

In the method for forming a film pattern, the predetermined process includes a thermal treatment of the second functional fluid placed in the groove, and the thermal treatment is used to form a receiving film having a porous member.

According to the present invention, the second functional fluid is thermally treated under predetermined conditions. Consequently, the receiving film can be favorably formed.

In the method for forming a film pattern, the placing the second functional fluid uses a liquid ejecting method.

According to the present invention, the second functional fluid can be placed by using the simple process while reducing the amounts of materials used.

In the method for forming a film pattern, on the substrate, the banks are used to form a first groove having a first width and a second groove is formed which is connected to the first groove and which has a second width, and the second functional fluid is placed in the first groove, and self-flowage of the second functional fluid placed in the first groove places the second functional fluid in the second groove.

According to the present invention, the second functional fluid is placed in the first groove. Consequently, the self-flowage (capillary phenomenon) of the second functional fluid placed in the first groove enables the second functional fluid to be placed in the second groove. Therefore, even if it is difficult to place the second functional fluid in the second groove from above the banks, the second functional fluid can be smoothly placed in the second groove. Further, since the second functional fluid can be placed in the second groove without the need to place the second functional fluid from above the banks, it is possible to prevent residues of the second functional fluid from disadvantageously remaining on the top surface of the banks.

In the method for forming a film pattern, the second width is equal to or smaller than the first width.

According to the present invention, the second functional fluid can be smoothly placed in the second groove by placing it in the first groove, which is wide, and without the need to place it in the second groove, which is narrow, from above the banks. Further, even though the second functional fluid is placed in the first groove from above the banks, the large width of the first groove makes it possible to avoid the disadvantage of splashing the second functional fluid on the top surface of the banks to form residues. Furthermore, the small width of the small groove allows the second functional fluid to be smoothly placed in the second groove as a result of the capillary phenomenon. Thus, since the second functional fluid can be smoothly placed in the second groove, which is narrow, the film pattern can be formed of thin lines (i.e., a very fine film pattern can be formed).

In the method for forming a film pattern, on the substrate, the banks are used to form a first groove extending in a first direction and a second groove is formed which is connected to the first groove and which extends in a second direction, and the second functional fluid is placed in the first groove, and self-flowage of the second functional fluid placed in the first groove places the second functional fluid in the second groove.

According to the present invention, the second functional fluid is placed in the first groove. Consequently, the second functional fluid can be placed, as a result of self-flowage, in the second groove, extending in the direction different from that in which the first groove extends.

In the method for forming a film pattern, the functional fluid is placed in the first groove, and self-flowage of the functional fluid placed in the first groove places the functional fluid in the second groove.

According to the present invention, the functional fluid is placed in the first groove in which the receiving film is provided. Consequently, the self-flowage (capillary phenomenon) of the functional fluid placed in the first groove enables the functional fluid to be placed in the second groove. Therefore, even if it is difficult to place the functional fluid in the second groove from above the banks, the functional fluid can be smoothly placed in the second groove. Further, since the functional fluid can be placed in the second groove without the need to place the functional fluid from above the banks, it is possible to prevent residues of the functional fluid from disadvantageously remaining on the top surface of the banks. Further, the functional fluid can be smoothly placed in the second groove by placing it in the first groove, which is wide, and without the need to place it in the second groove, which is narrow, from above the banks. Furthermore, even though the functional fluid is placed in the first groove from above the banks, the large width of the first groove makes it possible to avoid the disadvantage of splashing the functional fluid on the top surface of the banks to form residues. Moreover, the small width of the small groove allows the functional fluid to be smoothly placed in the second groove as a result of the capillary phenomenon. Since the receiving film is provided in the first and second grooves, the functional fluid is absorbed by and favorably held in the receiving film. Therefore, a film pattern with a desired shape can be formed. Since the functional fluid can be smoothly placed in the second groove, which is narrow, the film pattern can be formed of thin lines (i.e., a very fine film pattern can be formed).

In the method for forming a film pattern, the functional fluid contains fine conductive grains. Further, the functional fluid contains a material that develops conductivity when subjected to a thermal or optical treatment.

According to the present invention, the film pattern is a conductive wiring pattern and is thus applicable to various devices. Further, by using a light emitting element forming material such as an organic EL or an R, G, and B ink materials in addition to the fine conductive grains, the film pattern can be applied to the manufacture of an organic EL apparatus or a liquid crystal display apparatus having a color filter.

In the method for forming a film pattern, the functional fluid and the second functional fluid are substantially the same.

According to the present invention, the second functional fluid used to form a receiving film and the functional fluid used to form a film pattern are composed of the same fluid (the same composition and physical properties). This enables the receiving film (porous member) based on the functional fluid to absorb the functional fluid. As a result, a dense film pattern can be formed. The term “same fluid (the same composition and physical properties)” as used in the specification means that the functions (composition and physical properties) of the film pattern into which the functional fluid is converted are the same as those of the second film pattern into which the second functional fluid is converted. Accordingly, a liquid component (solvent) contained in the functional fluid may be the same as or different from that (solvent) contained in the second functional fluid.

In the method for forming a film pattern, the functional fluid and the second functional fluid are different.

According to the present invention, the type (composition and physical properties) of the second functional fluid which has a favorable receptivity to the functional fluid can be appropriately selected depending on the type (composition and physical properties) of the functional fluid. Further, it is possible to appropriately select each of the functional fluid and the second functional fluid and provide a film pattern formed with the functions of each of the functional fluid and the second functional fluid, or to control (adjust) the functions of the film pattern formed. That is, a film pattern having various functions can be formed. The liquid component (solvent) contained in the functional fluid may be the same as or different from that (solvent) contained in the second functional fluid.

In the method for forming a film pattern, the placing the functional fluid uses a liquid ejecting method.

According to the present invention, the functional fluid can be placed by using the simple process while reducing the amounts of materials used.

The present invention provides a method for forming a film pattern by placing a functional fluid on a substrate, the method includes forming banks having a predetermined pattern on the substrate, placing a second functional fluid in a first groove formed by the banks and placing the second functional fluid in a second groove connected to the first groove as a result of self-flowage of the second functional fluid placed in the first fluid, executing a predetermined process on the second functional fluid placed in the first and second grooves to convert the second functional fluid into a film, and placing the functional fluid on the film.

According to the present invention, the second functional fluid is placed in the first groove in which the receiving film is provided. Consequently, the self-flowage (capillary phenomenon) of the second functional fluid placed in the first groove enables the second functional fluid to be placed in the second groove. Therefore, even if it is difficult to place the second functional fluid in the second groove from above the banks, the second functional fluid can be smoothly placed in the second groove. Since the second functional fluid can be placed in the second groove without the need to place the functional fluid from above the banks, it is possible to prevent residues of the second functional fluid from disadvantageously remaining on the top surface of the banks. Further, the first functional fluid is placed in the first groove in which the film based on the second functional fluid is placed. Consequently, the first functional fluid can be smoothly placed in the second groove as a result of the self-flowage (capillary phenomenon) of the first functional fluid placed in the first groove. Furthermore, as in the case of the second functional fluid, it is possible to prevent residues of the first functional fluid from disadvantageously remaining on the top surface of the banks. Moreover, the first functional fluid is placed on the film provided in the first and second grooves. Consequently, the shape of the first functional fluid placed in the groove can be successfully maintained using the functions of the film. Therefore, a film pattern with a desired shape can be formed.

In the method for forming a film pattern, the predetermined process includes converting the second functional fluid placed in the first and second grooves into a receiving film having receptivity to the first functional fluid.

According to the present invention, the second functional fluid is converted into the receiving film located in the first and second grooves. The functional fluid placed on the receiving film is absorbed by and favorably held in the receiving film. Therefore, the first functional fluid can be appropriately placed in the groove between the banks. This enables the formation of a film pattern with a desired shape.

Further, even if part of the functional fluid splashes on the top surface of the banks when the functional fluid is placed in the groove, the receiving film can absorb the functional fluid to draw the functional fluid lying on the top surface of the banks, into the groove. This makes it possible to prevent residues of the functional fluid from disadvantageously remaining on the top surface of the banks. It is thus possible to prevent the degradation of the device characteristics resulting from the residues.

In the method for forming a film pattern, a dike portion is provided at positions of the first groove other than a connecting portion in which the first groove and the second groove are connected together.

According to the present invention, the dike portion causes the second functional fluid (or first functional fluid) placed between the connecting portion and dike portion of the first groove to flow to the connecting portion. Therefore, the second functional fluid (or the first functional fluid) flows through the connecting portion into the second groove smoothly.

In the method for forming a film pattern, the first groove and the second groove have different widths. Further, the width of the second groove is equal to or smaller than that of the first groove.

According to the present invention, the functional fluid can be smoothly placed in the second groove by placing it in the first groove, which is wide, and without the need to place it in the second groove, which is narrow, from above the banks. Furthermore, even though the functional fluid is placed in the first groove from above the banks, the large width of the first groove makes it possible to avoid the disadvantage of splashing the functional fluid on the top surface of the banks to form residues. Moreover, the small width of the second groove allows the functional fluid to be smoothly placed in the second groove as a result of the capillary phenomenon. Since the functional fluid can be smoothly placed in the second groove, which is narrow, the film pattern can be formed of thin lines (i.e., a very fine film pattern can be formed).

In the method for forming a film pattern, the first groove and the second groove are formed to extend in different directions.

According to the present invention, the second functional fluid is placed in the first groove. Consequently, the second functional fluid can be placed, as a result of self-flowage, in the second groove, extending in the direction different from that in which the first groove extends.

The present invention provides a method for forming a film pattern by placing a functional fluid on a substrate, the method includes forming banks having a predetermined pattern on the substrate, providing a first groove formed by the banks and a second groove connected to the first groove and having a smaller width than the first groove and providing a receiving film having receptivity to the functional fluid, in at least the second groove, and feeding the functional fluid from above the second groove to place the functional fluid in the second groove on which the receiving film is provided.

According to the present invention, when the banks are used to form the first groove and the second groove connected to the first groove and having the smaller width than the first groove, the receiving film is provided in at least the second groove. Accordingly, when the functional fluid is fed from above the second groove on the basis of, for example, a liquid ejecting method, even if part of the functional fluid splashes on the top surface of the banks, the receiving film can absorb the functional fluid to draw the functional fluid lying on the top surface of the banks, into the second groove. This makes it possible to prevent residues of the functional fluid from disadvantageously remaining on the top surface of the banks. It is thus possible to prevent the degradation of the device characteristics resulting from the residues.

The functional fluid supplied to the second groove is absorbed by and favorably held in the receiving film. Therefore, a film pattern with a desired shape can be formed.

The present invention provides a method for manufacturing a device, the method includes forming a film pattern on a substrate, the film pattern is formed on the substrate using the method for forming a film pattern as described above.

According to the present invention, it is possible to obtain a device having a desired pattern shape and a dense film pattern.

An electro-optical apparatus according to the present invention includes a device manufactured using the method for manufacturing a device as described above. Further, an electronic apparatus according to the present invention includes the above electro-optical apparatus. According to the present invention, an electro-optical apparatus and an electronic apparatus can be obtained that have wiring patterns formed at desired positions and in desired states.

A method for manufacturing an active matrix substrate according to the present invention includes forming gate wiring on a substrate, forming a gate insulating film on the gate wiring, stacking a semiconductor layer via the gate insulating film, forming a source electrode and a drain electrode on the gate insulating layer, placing an insulating material on the source electrode and the drain electrode, and forming a pixel electrode electrically connected to the drain electrode, and wherein at least one of the forming gate wiring, the forming a source electrode and a drain electrode, and the forming a pixel electrode has forming banks having a predetermined pattern on the substrate, providing a receiving film comprising a porous member, in a groove between the banks, and placing the functional fluid on the receiving film.

According to the present invention, droplets can be arranged at desired positions in a desired state. This makes it possible to manufacture an active matrix substrate exhibiting a desired performance.

A method for manufacturing an active matrix substrate according to the present invention includes forming gate wiring on a substrate, forming a gate insulating film on the gate wiring, stacking a semiconductor layer via the gate insulating film, forming a source electrode and a drain electrode on the gate insulating layer, placing an insulating material on the source electrode and the drain electrode, and forming a pixel electrode electrically connected to the drain electrode, and wherein at least one of the forming gate wiring, the forming a source electrode and a drain electrode, and the forming a pixel electrode has forming banks having a predetermined pattern on the substrate, placing a second functional fluid in a first groove formed by the banks and placing the second functional fluid in a second groove connected to the first groove as a result of self-flowage of the second functional fluid placed in the first fluid executing a predetermined process on the second functional fluid placed in the first and second grooves to convert the second functional fluid into a film, and placing the first functional fluid on the film.

According to the present invention, droplets can be arranged at desired positions in a desired state. This makes it possible to manufacture an active matrix substrate exhibiting a desired performance.

A method for manufacturing an active matrix substrate according to the present invention includes forming gate wiring on a substrate, forming a gate insulating film on the gate wiring, stacking a semiconductor layer via the gate insulating film, forming a source electrode and a drain electrode on the gate insulating layer, placing an insulating material on the source electrode and the drain electrode, and forming a pixel electrode electrically connected to the drain electrode, and wherein at least one of the forming gate wiring, the forming a source electrode and a drain electrode, and the forming a pixel electrode has forming banks having a predetermined pattern on the substrate, providing a first groove formed by the banks and a second groove connected to the first groove and having a smaller width than the first groove and providing a receiving film having receptivity to the functional fluid, in at least the second groove, and feeding the functional fluid from above the second groove to place the functional fluid in the second groove on which the receiving film is provided.

According to the present invention, droplets can be arranged at desired positions in a desired state. This makes it possible to manufacture an active matrix substrate exhibiting a desired performance.

### BRIEF DESCRIPTION OF THE DRAWINGS

FIG. 1 is a schematic perspective view of a droplet ejecting apparatus.

FIG. 2 is a diagram illustrating the principle of ejection of a liquid material based on a piezo system.

FIG. 3 is a flowchart showing an embodiment of a method for forming a film pattern according to the present invention.

FIG. 4A to FIG. 4D are schematic diagrams showing an example of a procedure of forming a film pattern according to the present invention.

FIG. 5A to FIG. 5D are schematic diagrams showing an example of a procedure of forming a film pattern according to the present invention.

FIG. 6 is a schematic diagram illustrating the effects of the method for forming a film pattern according to the present invention.

FIG. 7A and FIG. 7B are a table and a diagram illustrating an example of experiment results.

FIG. 8 is a schematic diagram showing another embodiment of the method for forming a film pattern according to the present invention.

FIG. 9A to FIG. 9C are schematic diagrams showing another embodiment of the method for forming a film pattern according to the present invention.

FIG. 10A to FIG. 10C are schematic diagrams showing another embodiment of the method for forming a film pattern according to the present invention.

FIG. 11 is a schematic diagram showing another embodiment of the method for forming a film pattern according to the present invention.

FIG. 12 is a schematic diagram showing another embodiment of the method for forming a film pattern according to the present invention.

FIG. 13 is a schematic diagram showing another embodiment of the method for forming a film pattern according to the present invention.

FIG. 14 is a schematic diagram showing another embodiment of the method for forming a film pattern according to the present invention.

FIG. 15A and FIG. 15B are schematic diagrams showing another embodiment of the method for forming a film pattern according to the present invention.

FIG. 16 is a schematic diagram showing another embodiment of the method for forming a film pattern according to the present invention.

FIG. 17 is a schematic diagram showing another embodiment of the method for forming a film pattern according to the present invention.

FIG. 18 is a schematic diagram showing another embodiment of the method for forming a film pattern according to the present invention.

FIG. 19 is a schematic diagram showing an example of a substrate having a thin film transistor.

FIG. 20 is a diagram illustrating a process of manufacturing a thin film transistor.

FIG. 21 is a diagram illustrating the process of manufacturing a thin film transistor.

FIG. 22 is a diagram illustrating the process of manufacturing a thin film transistor.

FIG. 23 is a diagram illustrating the process of manufacturing a thin film transistor.

FIG. 24 is a plan view of a liquid crystal display apparatus as viewed from an opposite substrate.

FIG. 25 is a sectional view taken along line H-H′ in FIG. 24.

FIG. 26 is an equivalent circuit diagram of the liquid crystal display apparatus.

FIG. 27 is a partly enlarged sectional view of the liquid crystal display apparatus.

FIG. 28 is a partly enlarged sectional view of an organic EL apparatus.

FIG. 29 is an exploded perspective view of a plasma type display apparatus.

FIG. 30 is a diagram showing another embodiment of the liquid crystal display apparatus.

FIG. 31 is an exploded perspective view of a non-contact type card medium.

FIG. 32A to FIG. 32C are diagrams showing specific examples of electronic apparatuses according to the present invention.

### DETAILED DESCRIPTION OF THE INVENTION

With reference to the drawings, description will be given of a method for forming a film pattern and a method for manufacturing a device according to the present invention. In the present embodiment, description will be given of an example in which a functional fluid (ink) containing a conductive material is ejected, in droplet form, from ejection nozzles in a droplet ejecting head on the basis of a liquid ejecting method, so that a wiring pattern (film pattern) consisting of a conductive film is formed on a substrate.

(Device Manufacturing Apparatus)

First, description will be given of a device manufacturing apparatus used to manufacture a device according to the present invention. As the device manufacturing apparatus, a droplet ejecting apparatus (ink jet apparatus) that manufactures a device by ejecting (feeding) droplets from a droplet ejecting head to a substrate.

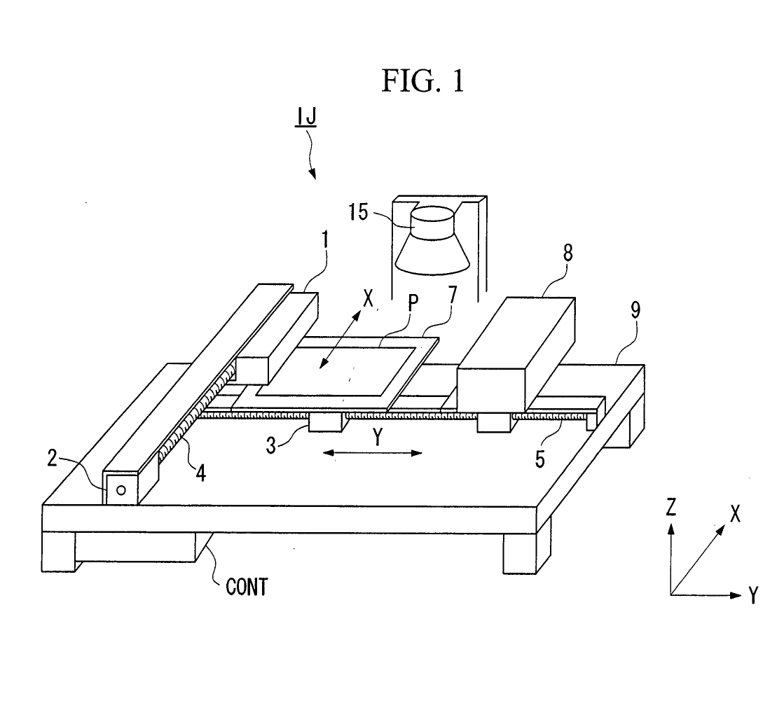

FIG. 1 is a perspective view generally showing the configuration of a droplet ejecting apparatus IJ.

In FIG. 1, the droplet ejecting apparatus IJ comprises a droplet ejecting head 1, an X-axis direction driving shaft 4, a Y-axis direction driving shaft 5, a control device CONT, a stage 7, a cleaning mechanism 8, a base 9, and a heater 15.

The stage 7 supports a substrate P to which the droplet ejecting head 1 ejects (places) a functional fluid (ink). The stage 7 comprises a fixing mechanism (not shown) that fixes the substrate P to a reference position.

The droplet ejecting head 1 is of a multi-nozzle type has a plurality of ejection nozzles. A longitudinal direction of the droplet ejecting head 1 coincides with an X axis direction. The plurality of ejection nozzles are provided in a bottom surface of the droplet ejecting head 1 in parallel in the X axis direction at regular intervals. The functional fluid is ejected from the ejection nozzles in the droplet ejecting head 1 to the substrate P, supported on the stage 7.

An X axis direction driving motor 2 is connected to the X axis direction driving shaft 4. The X axis direction driving motor 2 is a stepping motor or the like. When the control device CONT supplies a driving signal for an X axis direction to the X axis direction driving motor 2, the motor 2 rotates the X axis direction driving shaft 4. When the X axis direction driving shaft 4 rotates, the droplet ejecting head 1 moves in the X axis direction.

The Y axis direction guide shaft 5 is fixed to the base 9. The stage 7 includes a Y axis direction driving motor 3. The Y axis direction driving motor 3 is a stepping motor or the like. When the control device CONT supplies a driving signal for a Y axis direction to the Y axis direction driving motor 3, the motor 3 moves the stage 7 in a Y axis direction.

The control device CONT supplies the droplet ejecting head 1 with a voltage for controlling the ejection of droplets. Moreover, the control device CONT supplies the X axis direction driving motor 2 with a driving pulse signal that controls the movement of the droplet ejecting head 1 in the X axis direction. The control device CONT supplies the Y axis direction driving motor 3 with a driving pulse signal that controls movement of the stage 7 in the Y axis direction.

The cleaning mechanism 8 cleans the droplet ejecting head 1. The cleaning mechanism 8 includes a Y axis direction driving motor (not shown). The Y axis direction driving motor drives the cleaning mechanism 8 so that the cleaning mechanism 8 moves along the Y axis direction guide shaft 5. The control device CONT also controls the movement of the cleaning mechanism 8.

The heater 15 is means for thermally treating the substrate P by lamp annealing. The heater 15 evaporates and dries a solvent contained in the ink applied to the substrate P. The control device CONT also controls power-on and power-off of the heater 15.

The droplet ejecting apparatus IJ ejects droplets to the substrate P while relatively scanning the droplet ejecting head 1 and the stage 7, which supports the substrate P. In the description below, the Y axis direction is a scanning direction, while the X axis direction, which is orthogonal to the Y axis direction, is a non-scanning direction. Therefore, the ejection nozzles in the droplet ejecting head 1 are formed in parallel in the X axis direction, the non-scanning direction, at regular intervals. In FIG. 1, the droplet ejecting head 1 is placed at a right angle to a direction in which the substrate P advances. However, the angle of the droplet ejecting head 1 may be adjusted so as to cross the advancing direction of the substrate P.

Thus, the pitch between the nozzles can be adjusted on the basis of the angle of the droplet ejecting head 1. Further, the distance between the substrate P and a nozzle surface may be adjustable.

Ejecting techniques for the liquid ejecting method include a charging control system, a pressure vibrating system, an electromechanical transducing system, an electrothermal transducing system, and an electrostatic sucking system.

The charging control system uses a charging electrode to apply charges to a material. The charging control system them uses a polarizing electrode to control a direction in which the material flies, to eject the material from the ejection nozzles.

The pressure vibrating system applies a very high pressure of about 30 kg/cm² to the material to eject the material toward the tips of the nozzles. Without a control voltage, the material moves straight and is ejected from the ejection nozzles. The application of the control voltage causes electrostatic repulsion between masses of the material. Thus, the material scatters and is not ejected from the ejection nozzles.

The electromechanical transducing system utilizes the tendency of a piezo element to be deformed upon receiving a pulse-like electric signal. The piezo element is deformed to exert pressure, via a flexible substance, in a space in which the material is stored. The material is pushed out of the space and is ejected from the ejection nozzles.

The electrothermal transducing system uses a heater provided in a space in which a material is stored, to rapidly vaporize the material to generate bubbles. Thus, the pressure of the bubbles is used to eject the material from the space. The electrostatic sucking system exerts a very low pressure in the space in which the material is stored, to form a meniscus of the material in the ejection nozzles. In this state, an electrostatic attractive force is applied to draw out the material. It is also possible to apply a system that utilizes a variation in the viscosity of the fluid caused by electric fields or a system that uses discharge sparks to scatter the material. The liquid ejecting method is advantageous in that the material is efficiently used and in that a desired amount of material can be adequately placed at desired positions. The amount of a droplet of the functional fluid ejected using the liquid ejecting method is, for example, 1 to 300 nanograms.

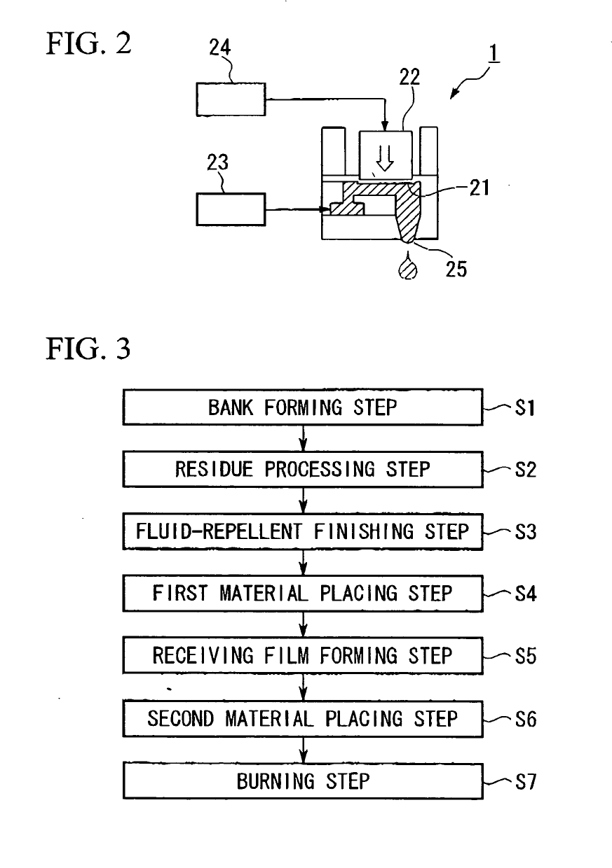

FIG. 2 is a diagram illustrating the principle of ejection of the functional fluid based on the electromechanical transducing system (piezo system).

In FIG. 2, a piezo element 22 is installed adjacent to a liquid channel 21 that accommodates the functional fluid. The liquid channel 21 is supplied with the functional fluid via a functional fluid supplying system 23 including a material tank that accommodates the functional fluid. The piezo element 22 is connected to the driving circuit 24. A voltage is applied to the piezo element 22 via the driving circuit 24 to deform the piezo element 22. The liquid chamber 21 is thus deformed to eject the functional fluid from an ejection nozzle 25. In this case, the value of the applied voltage is varied to control the amount of distortion of the piezo element 22. Further, the frequency of the applied voltage is varied to control the direction speed of the piezo element 22. The ejection of droplets based on the piezo system does not involve heating of the material. Accordingly, this droplet ejection has the advantage of avoiding adverse effects on the composition of the material.

(Functional Fluid)

Now, description will be given of a functional fluid used to form a wiring pattern.

The functional fluid used to form a wiring pattern may be a dispersed fluid in which fine conductive grains are dispersed in a dispersing medium, or a solution in which an organic silver compound or nano-grains of silver oxide are dispersed in a solvent (dispersing medium). The fine conductive grains may be, for example, fine metal grains containing any one of gold, silver, copper, aluminum, palladium, and nickel, their oxides, or fine grains of a conductive polymer or a superconductor. The surfaces of these fine conductive grains may be coated with an organic substance or the like in order to allow the grains to be dispersed better. The fine conductive grains have a grain size of at least 1 nm and at most 0.1 μm. If the grain size is larger than 0.1 μm, the ejection nozzles in the droplet ejecting head, described later, may be clogged. On the other hand, if the grain size is smaller than 1 nm, the volumetric ratio of a coating agent to the fine conductive grains is increased. As a result, the rate of the total film obtained which is taken up by the organic substance becomes excessive organic substance.

The dispersing medium is not particularly limited provided that it can disperse the above fine conductive material and is not aggregated. Examples of the dispersing media include, for example, water, alcohols such as methanol, ethanol, propanol, and butanol, hydrocarbon-based compounds such as n-heptane, n-octane, decane, dodecane, tetradecane, toluene, xylene, cymene, durene, indene, dipentene, tetrahydronaphthalene, decahydronaphthalene, and cyclohexylbenzene, ether-based compounds such as ethyleneglycoldimethylether, ethyleneglycoldiethylether, ethyleneglycolmethylethylether, diethyleneglycoldimethylether, diethyleneglycoldiethylether, diethyleneglycolmethylethylether, 1,2-dimethoxyethane, bis(2-methoxyethyl) ether, and p-dioxane, and polarized compounds such as propylene carbonate, γ-butyrolactone, N-methyl-2-pyrrolidone, dimethylformamide, dimethylsulfoxide, and cyclehexanone. Of these compounds, water, the alcohols, the hydrocarbon-based compounds, and the ether-based compounds are preferable in terms of the capability of dispersing fine grains, the stability of the dispersed fluid, and the ease with which the dispersing medium can be applied to the liquid ejecting method. More preferred dispersing media are water and the hydrocarbon-based compounds.

The dispersed fluid of the fine conductive grains preferably has a surface tension of at least 0.02 N/m and at most 0.07 N/m. When the functional fluid (ink) is ejected on the basis of the liquid ejecting method, if the surface tension is 0.02 N/m, the functional fluid more easily wets the nozzle surface. Consequently, the flight path of the functional fluid is likely to be curved. If the surface tension exceeds 0.07 N/m, the shape of the meniscus at the tips of the nozzles is unstable. Consequently, it is difficult to control the amount of functional fluid ejected and ejection timings. To adjust the surface tension, a small amount of, for example, a fluorine-based, silicone-based, or nonion-based surface tension regulator may be added to the dispersed fluid to the extent that the angle of contact with the substrate is not sharply reduced. The nonion-based surface tension regulator is useful for allowing the functional fluid to wet the substrate more easily, allowing the film to be more appropriately leveled, and preventing the formation of very small concaves and convexes on the film. The surface tension regulator may contain an organic compound such as alcohol, ether, ester, or ketone as required.

The dispersed fluid preferably has a viscosity of at least 1 mPa·s and at most 50 mPa·s. When the liquid ejecting method is used to eject the functional fluid in droplet form, if the viscosity is smaller than 1 mPa·s, the periphery of the nozzles is likely to be contaminated with the outflow of the functional fluid. If the viscosity is larger than 50 mPa·s, the nozzle holes are more frequently clogged. This makes it difficult to eject droplets smoothly.

The substrate on which a wiring pattern is formed may be any of various substrates including glass, quartz glass, an Si wafer, a plastic film, and a metal plate. Further, a semiconductor film, a metal film, a dielectric film, an organic film, or the like may be formed on a surface of any of these material substrates as a base layer.

(Method for Forming Wiring Pattern (First Embodiment))

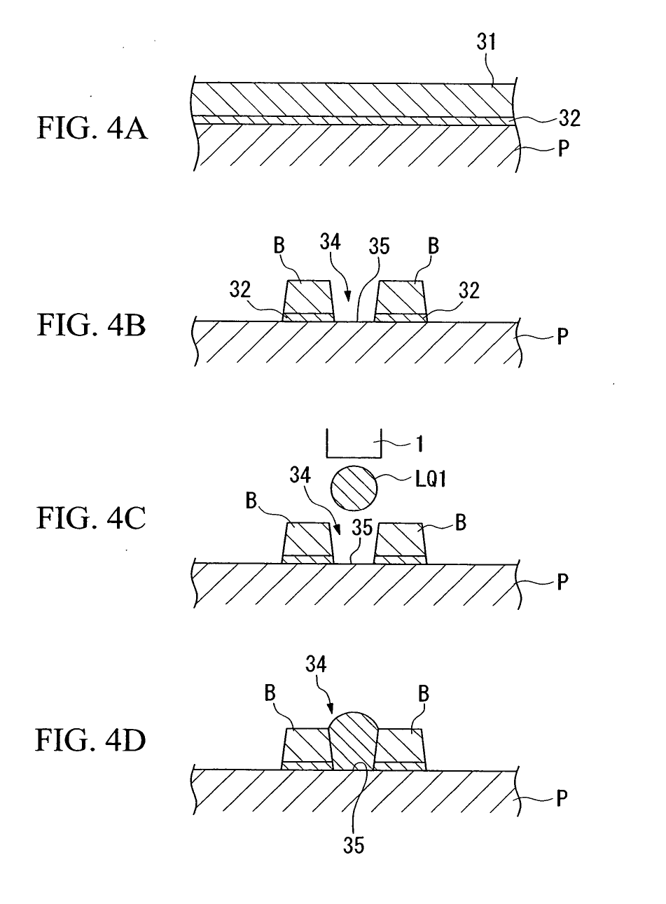

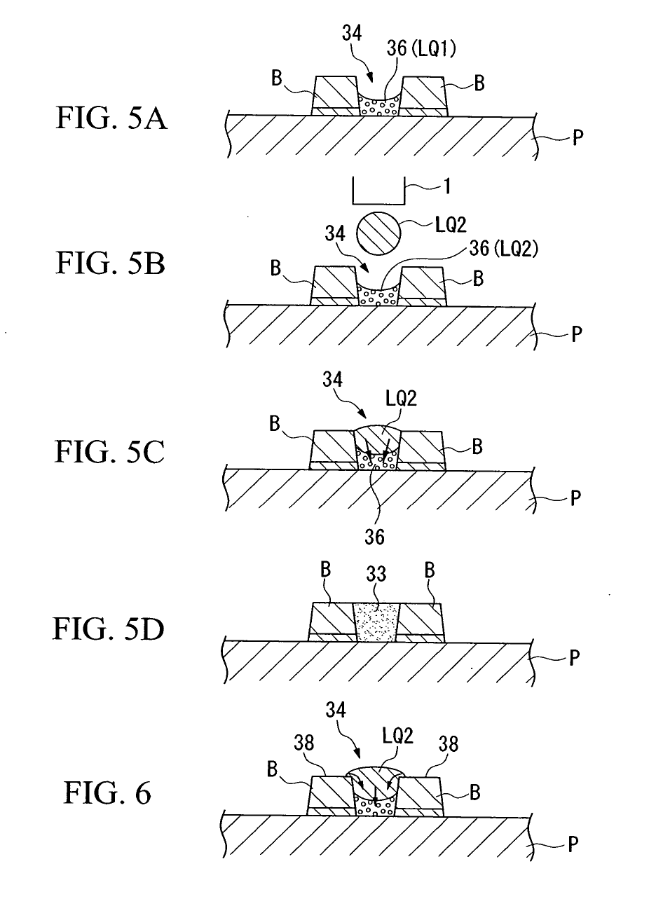

Now, with reference to FIGS. 3, 4A to 5D, description will be given of a first embodiment of a method for forming a wiring pattern according to the present invention. FIG. 3 is a flowchart showing an example of a method for forming a wiring pattern according to the present embodiment. FIGS. 4A and 5D are schematic diagrams showing a forming procedure.

As shown in FIG. 3, the method for forming a wiring pattern according to the present embodiment forms a wiring pattern on a substrate by placing a wiring pattern forming functional fluid on the substrate. The method includes a bank forming step S1 of providing banks corresponding to a wiring pattern on the substrate, a residue processing step S2 of removing residues from between the banks, a fluid-repellent finishing step S3 of providing the banks with fluid repellence, a first material placing step S4 of placing, on the basis of the liquid ejecting method, a functional fluid (second functional fluid) in the groove between the banks from which residues have been removed, a receiving film forming step S5 of executing a predetermined process on the functional fluid placed in the groove between the grooves in the first material placing step S4 to convert the functional fluid into a receiving film, a second material placing step S6 of placing a functional fluid (first functional fluid) on the receiving film formed in the receiving film forming step S5, and a burning step S7.

Each of the steps will be described below in detail. According to the present embodiment, a glass substrate is used as the substrate P. Further, according to the present embodiment, the wiring pattern forming functional fluid is a dispersed fluid in which fine conductive grains are dispersed in a solvent (dispersing medium). According to the present embodiment, the fine conductive grains are fine silver grains. The fine conductive grams may be fine metal grains containing gold, copper, palladium, or nickel, or fine grains of a conductive polymer or a superconductor, as described above. Further, the wiring pattern forming functional fluid may be obtained by dispersing an organic silver compound in diethyleneglycoldiethylether.

(Bank Forming Step)

Before application of an organic material, an HMDS treatment is executed on the substrate as a surface modifying treatment. The HMDS process is a method of applying hexamethyldisilazane ((CH₃)₃SiNHSi(CH₃)₃) in vapor form. This forms an HMDS layer 32 on the substrate P as an adhesion layer that improves the adhesion between the banks and the substrate P as shown in FIG. 4A.

The banks function as partitioning members. The banks can be formed by an arbitrary method such as a photolithography process or a printing process. For example, with the photolithography process, an organic substance-based photosensitive material 31 is coated on the HMDS layer 32 on the substrate P in accordance with the height of the banks using a predetermined method such as spin coating, spray coating, roll coating, die coating, or dip coating. A resist layer is coated on the photosensitive material 31. Then, the resist layer is masked in conformity with the bank shape (wiring pattern). The resist is then exposed and developed so as to be partly left in conformity with the bank shape. Finally, the bank material is etched so as to be removed except for its mask portions. Alternatively, the banks may be composed of two or more layers including a lower layer consisting of an inorganic or organic material that is lyophilic to the functional fluid and an upper layer consisting of an organic material that is repellent to the fluid. Thus, as shown in FIG. 4B, banks B and B are provided so as to surround the periphery of an area in which a wiring pattern is to be formed.

The organic material forming the banks may inherently repel the functional fluid or may be an insulating organic material that can be made fluid-repellent (fluoridated) by a plasma process and which contacts tightly with the underlying substrate and which is easily patterned by photolithography. For example, it is possible to use a polymer material such as an acrylic resin, a polyimide resin, an olefin resin, a phenol resin, or a melamine resin.

(Residue Processing Step)

Once the banks B and B are formed on the substrate P, a fluoridating process is executed. The fluoridating process uses, for example, a 2.5% water solution of hydrofluoric acid to carry out etching to remove the HMDS layer 32 from between the banks B and B. In the fluoridating process, the banks B and B function as a mask. A part of the HMDS layer 32, an organic substance, is removed which part is located at a bottom portion 35 of a groove portion 34 formed between the banks B and B. This removes a part of the HMDS which corresponds to residues.

(Fluid-Repellent Finishing Step)

Subsequently, a fluid-repellent finishing process is executed on the banks B to provide their surfaces with fluid repellence. The fluid-repellent finishing process may be, for example, a plasma process using tetrafluoromethane as a process gas in an air atmosphere (CF₄ plasma process). Conditions for the CF₄ plasma process are as follows: plasma power is 50 to 1,000 W, the flow rate of a carbon tetrafluoride gas is 50 to 100 mL/min, the speed at which the base is conveyed to a plasma discharge electrode is 0.5 to 1,020 mm/sec, and the temperature of the base is 70 to 90° C. The process gas is not limited to tetrafluoromethane (carbon tetrafluoride) but may be any of the other fluorocarbon-based gases.

Such a fluid-repellent finishing process introduces a fluorine group into the resin constituting the banks B and B to provide the banks B and B with a high fluid repellence. The O₂ plasma process serving as a lyophilic finishing process may be executed before the formation of the banks B and B. However, the acrylic resin, polyimide resin, and the like are more likely to be fluoridated (made fluid-repellent) when previously processed using O₂ plasma. Accordingly, the O₂ plasma process is preferably executed after the banks B have been formed.

An exposed part of the substrate P between the banks is slightly affected by the fluid-repellent finishing process on the banks B and B. However, if the substrate P consists of glass or the like, the introduction of the fluorine group based on the fluid-repellent finishing process is avoided. Consequently, the lyophilicity, that is, wettability, of the substrate, is not substantially impaired. Further, the fluid-repellent finishing process for the banks B and B may be omitted by forming them using a fluid-repellent material (for example, a resin material having the fluorine group).

In this case, the hydrofluoric acid process may fail to perfectly remove the HMDS (organic substance) from the bottom portion 35 between the banks B and B, or may leave the resist (organic substance), used to form the banks B and B, in the bottom portion 35 between the banks B and B. Thus, a residue process is preferably executed on the substrate P after the fluid-repellent finishing step in order to remove the organic substance (resist or HMDS) used to form the banks B and B, from the bottom portion 35 between the banks B and B.

The residue process may be, for example, an ultraviolet (UV) irradiation process of executing a residue process by irradiation with ultraviolet rays or an O₂ plasma process of using oxygen in the air atmosphere as a process gas. It is also possible to execute an etching process using an acid (H₂SO₄, HF, or HNO₃).

If the substrate P is made of glass, its surface is lyophilic to the wiring pattern forming material. When the O₂ plasma process or ultraviolet irradiation process is executed for the residue process as in the case of the present embodiment, the lyophilicity of the exposed surface (bottom portion 35) of the substrate P between the banks B, B is improved. The O₂ plasma process, the ultraviolet irradiation process, and etching with the acid (HF) are preferably executed so that the angle of contact of the bottom portion 35 between the banks with the functional fluid is at most 15°.

(First Material Placing Step)

Then, the liquid ejecting method executed by the droplet ejecting apparatus IJ is used to place droplets of a functional fluid LQ1 used to form a receiving film, in the bottom portion 34 between the banks B and B. In the first material placing step, the functional fluid LQ1 is ejected from the droplet ejecting head 1 in droplet form as shown in FIG. 4C.

In the present embodiment, the functional fluid (second functional fluid) LQ1 placed in the groove portion 34 in the first material placing step S4 is the same as a functional fluid (first functional fluid) LQ2 placed on the receiving film in the second material placing step S6. That is, according to the present embodiment, the functional fluid LQ1 used to form a receiving film is the same as the functional fluid LQ2 used to form a wiring pattern.

An ejected droplet of the functional fluid LQ1 is placed in the groove portion 34 between the banks B and B on the substrate P as shown in FIG. 4D. Conditions for droplet ejection include, for example, an ink weight of 4 ng/dot and an ink speed (ejection speed) of 5 to 7 m/sec. The atmosphere in which droplets are ejected is preferably set at a temperature of at most 60° C. and a humidity of at most 80%. This enables stable droplet ejections without clogging the ejection nozzles in the droplet ejecting head 1.

In this case, since the wiring pattern to-be-formed area (that is, the groove portion 34) to which droplets are to be ejected is surrounded by the banks B and B, the droplets can be prevented from spreading out from the predetermined position. Further, since the banks B and B are provided with fluid repellence, even if some of the ejected droplets rest on the banks B, they are repelled from the banks B because the bank surfaces repel the fluid. The droplets thus flow down into the groove portion 34 between the banks. Moreover, since the bottom portion 35 of the groove portion 34 from which the substrate P is exposed is lyophilic, the ejected droplets spread more readily in the bottom portion 35. This allows the ink to be uniformly placed within the predetermined position.

(Receiving Film Forming Step)

After a droplet of the functional fluid LO1 has been placed in the groove portion 34 on the substrate P, a drying process (thermal treatment) is executed under predetermined conditions in order to remove the dispersing medium, which is a liquid component, and to form a receiving film. The drying process may comprise using an ordinary hot plate or electric furnace or the like to heat the substrate P. According to the present embodiment, the substrate P is heated, for example, at about 180° C. for about 60 minutes. The atmosphere for the drying process may or may not be the air. For example, the drying process may be executed in a nitrogen (N₂) atmosphere.

Alternatively, the drying process can be achieved using a light irradiation process based on lamp annealing. A light source used for lamp annealing is not particularly limited. The light source may be, for example, an infrared lamp, a xenon lamp, a YAG laser, an argon laser, a carbonic acid gas laser, or an excimer laser such as XeF, XeCl, XeBr, KrF, KrCl, ArF, or ArCl. These light sources generally have an output of at least 10 W and at most 5,000 W. However, according to the present embodiment, it is sufficient to have an output of at least 100 W and at most 1,000 W.

According to the present embodiment, the functional fluid placed in the groove portion 34 is converted into a receiving film 36 as shown in FIG. 5A by optimizing drying conditions (thermal treatment conditions) for the functional fluid LQ1 placed in the groove portion 34 and drying the substrate P under the optimized drying conditions. The receiving film 36 exhibits receptivity to the functional fluid LQ2 placed in the second material placing step S6, which is executed next. The receiving film 36 is composed of a porous member. Drying under predetermined conditions enables the functional fluid LQ1 placed in the groove portion 34 to be converted into the receiving film 36, which consists of a porous member. According to the present embodiment, for example, heating at about 180° C. for about 60 minutes enables the functional fluid LQ1 placed in the groove portion 34 to be converted into the porous member.

(Second Material Placing Step)

After the receiving film 36 has been formed by drying the functional fluid LQ on the substrate P under the predetermined conditions, a droplet of the next functional fluid LQ2 is placed on the receiving film 36, provided in the groove portion 34, as shown in FIG. 5B. As shown in FIG SC, a droplet of the functional fluid LQ2 ejected from the droplet ejecting head 1 permeates through void portions of the receiving film 36, which consists of the porous member. The droplet is thus absorbed by and held in the receiving film 36. When the receiving film 36, provided first on the substrate P, is the porous member as described above, the second droplet of the functional fluid LQ2, placed next on the substrate P, is absorbed by the receiving film 36, which consists of the porous member. The droplet is thus favorably placed between the banks B and B.

(Burning Step)

After the ejecting step, the dispersing medium must be completely removed from the dried film in order to allow fine grains to contact appropriately with one another. Further, if a coating material such as an organic substance is coated on the surfaces of fine conductive grains in order to allow the grains to be dispersed better, this coating material must be removed. Thus, after the ejecting step, the substrate is thermally or optically treated.

The thermal or optical treatment is normally carried out in the air. However, the treatment may also be carried out in the atmosphere of an inert gas such as nitrogen, argon, or helium as required. The temperature for the thermal or optical treatment is appropriately determined taking into account the boiling point (vapor pressure) of the dispersing medium, the type or pressure of the atmosphere gas, thermal behavior such as the dispersion or oxidation of fine grains, the presence or amount of coating material, the heat resistant temperature of the base material, and the like. For example, to remove a coating material consisting of an organic substance, the substrate must be burned at about 300° C. Further, if the substrate is made of plastics or the like, it is preferably burned at at least the room temperature and at most 100° C.

The above steps ensure that the fine grains in the dried film subjected to the ejecting step contact electrically with one another. As shown in FIG. 5D, the dried film is converted into a wiring pattern 33 consisting of a conductive film.

After the burning step, the banks B and B, which are present on the substrate P, can be removed by an ashing peeling process. The ashing process may be plasma ashing, ozone ashing, or the like. Plasma ashing causes a plasma-processed oxygen gas or the like to react with the banks (resist) to vaporize, peel, and remove the banks. The banks are a solid substance composed of nitrogen, oxygen, and hydrogen, which react chemically with oxygen plasma to become CO₂, H₂O, and O₂. All these gases can be peeled off. On the other hand, the basic principle of the ozone ashing is the same as that of the plasma ashing. The ozone ashing decomposes O₃ (ozone) into a reactive gas O* (active oxygen). Then, the O* is caused to react with the banks. The banks react with the O* to become CO₂, H₂O, and O₂. All these gases are then peeled off. The ashing peeling process executed on the substrate P removes the banks from the substrate P.

When the receiving film 36 is provided in the groove portion 34 between the banks B and B as described above, the functional fluid LQ2 placed on the receiving film 36 is absorbed by and favorably held in the receiving film 36. Therefore, the functional fluid LQ2 can be successfully placed in the groove portion 34 between the banks B and B to form a wiring pattern 33 with a desired shape.

Even if part of the functional fluid LQ2 splashes on top surfaces 38 of the banks B when the functional fluid LQ2 is placed in the groove portion 34, as shown in the schematic diagram in FIG. 6, the receiving film 36 can absorb the functional fluid LQ2 to draw the functional fluid LQ2 lying on the top surfaces 38 of the banks B into the groove portion 34. This makes it possible to prevent residues of the functional fluid LQ2 from being present on the top surface of the banks 38. If residues of the functional fluid LQ2 containing a conductive material are placed on the top surfaces 38 of the banks B, when a current is conducted through the wiring pattern 33, a leak current may be generated in the residues on the top surfaces 38. If the wiring pattern 33 is applied to a thin film transistor (TFT), the leak current may degrade the characteristics of the TFT. However, the present invention can prevent the generation of residues on the top surfaces 38 of the banks B. This makes it possible to prevent the degradation of the device characteristics caused by the residues.

According to the present embodiment, the functional fluid LQ1 is placed in the groove portion 34 on the basis of the liquid ejecting method. Then, the drying process (thermal treatment) is executed on the functional fluid LQ2 to form the receiving film 36. However, of course, a method different from the droplet ejection may be used to place the functional fluid LQ1 in the groove portion 34. Alternatively, the receiving film forming material used to form the receiving film 36 need not be a liquid when placed in the groove portion 34.

According to the present embodiment, the functional fluid LQ1 placed on the substrate P in the first material placing step S4 is the same as a functional fluid LQ2 placed on the substrate P in the second material placing step S6. That is, the functional fluid LQ1 used to form a receiving film 36 is the same as the functional fluid LQ2 used to form a wiring pattern. Therefore, a dense wiring pattern 33 can be formed by causing the receiving film (porous member) 26 to absorb the functional fluid LQ2.

On the other hand, the functional fluid LQ1 used to form a receiving film 36 may be different from the functional fluid LQ2 used to form a wiring pattern. The receiving film placed in the groove portion 34 may have physical properties different from those of the functional fluid LQ2 placed on the receiving film 36. This makes it possible to appropriately select the type (composition and physical properties) of the receiving film 36 which has a favorable receptivity to the functional fluid LQ2 depending on the type (composition and physical properties) of the functional fluid LQ2. Further, it is possible to appropriately select each of the functional fluid LQ2 and the receiving film 36 and provide a wiring pattern (film pattern) formed 33 with the functions of each of the functional fluid LQ2 and the receiving film 36, or to control (adjust) the functions of the wiring pattern (film pattern) formed 33. That is, a wiring pattern (film pattern) having various functions can be formed.

Further, by using porous silica as the receiving film 36 and placing, on the receiving film 36, the functional fluid LQ2 used to form a wiring pattern and containing a conductive material, it is possible to form a wiring pattern 33 with a desired shape while preventing residues from being present on the top surfaces 38 of the banks B. A receiving film 36 containing porous silica can be provided in the groove portion 34 by placing a functional fluid LQ1 containing porous silica in the groove portion 34 on the basis of the liquid ejecting method and then drying (thermally treating) the functional fluid LQ1 under predetermined conditions. Also, as the receiving film 36, porous titanium oxide or porous alumina can be used instead of porous silica.

Further, for example, an organic silver compound may be placed in the first material placing step S4 and fine silver grains may be placed in the second material placing step S6. In contrast, fine silver grains may be placed in the first material placing step S4 and an organic silver compound may be placed in the second material placing step S6. Alternatively, for example, in the first material placing step S4, a dispenser may be used to place the functional fluid, and in the second material placing step S6, an ink jet head may be used to place the functional fluid.

In the description of the above embodiments, the functional fluid is placed between the banks on the substrate in the first and second material placing steps. However, of course, the functional fluid may be sequentially stacked in a plurality of material placing steps including a third material placing step separate from the first and second ones. In this case, the receiving film forming step can be provided between arbitrary ones of the plurality of material placing steps.

In the description of the above embodiments, the receiving film forming step is executed between a plurality of material placing steps. However, the receiving film forming step may be executed concurrently with a material placing step. For example, a droplet may be placed on the substrate P while using a heating apparatus (hot plate or the like) to heat the substrate P. Alternatively, a droplet may be placed while irradiating the substrate P with light. This also allows the receiving film to absorb and retain the functional liquid. Further, the receiving film forming step executed simultaneously with the placement of a droplet may be carried out concurrently with all or selected predetermined ones of the plurality of material placing steps.

As described above, when the receiving film 36, provided on the substrate P, is the porous member, the functional fluid LQ2 ejected from the ejection head 1 can be caused to permeate through the receiving film 36 on the substrate P. Accordingly, when plural layers of the functional fluid (film pattern) are stacked, the amount of droplets ejected may be gradually increased during the stacking.

In the description of the above embodiments, the functional fluid is obtained by dispersing fine conductive grains in a dispersing medium. However, the functional fluid may be obtained by, for example, dispersing a conductive material such as an organic silver compound in a solvent (dispersing medium) such as diethyleneglycoldiethylether. In this case, during the burning step, a thermal or optical treatment is executed on the functional fluid (organic silver compound) ejected onto the substrate, in order to make the functional fluid conductive. Then, organic components are removed from the organic silver compound while leaving silver grains. For example, the burning step is executed at about 200° C. in order to remove the organic components from the organic silver compound. This ensures that after the ejecting step, the fine grains in the dried film contact electrically with one another. The dried film is thus converted into a conductive film.

### (EXPERIMENTAL EXAMPLE 1)

To form a receiving film 36, the functional fluid LQ1 containing fine conductive grains was first placed in the groove portion 34 on the liquid ejecting method. Subsequently, the functional fluid LQ1 in the groove portion 34 was dried under a plurality of drying conductions to optimize the drying conditions. The experimental drying conditions included (1) allowing to stand for about 24 hours, (2) heating at 60° C. for about 5 minutes, (3) heating at 120° C. for about 5 minutes, (4) heating at 180° C. for about 60 minutes, (5) heating at 200° C. for about 60 minutes, and (6) heating at 250° C. for about 60 minutes.

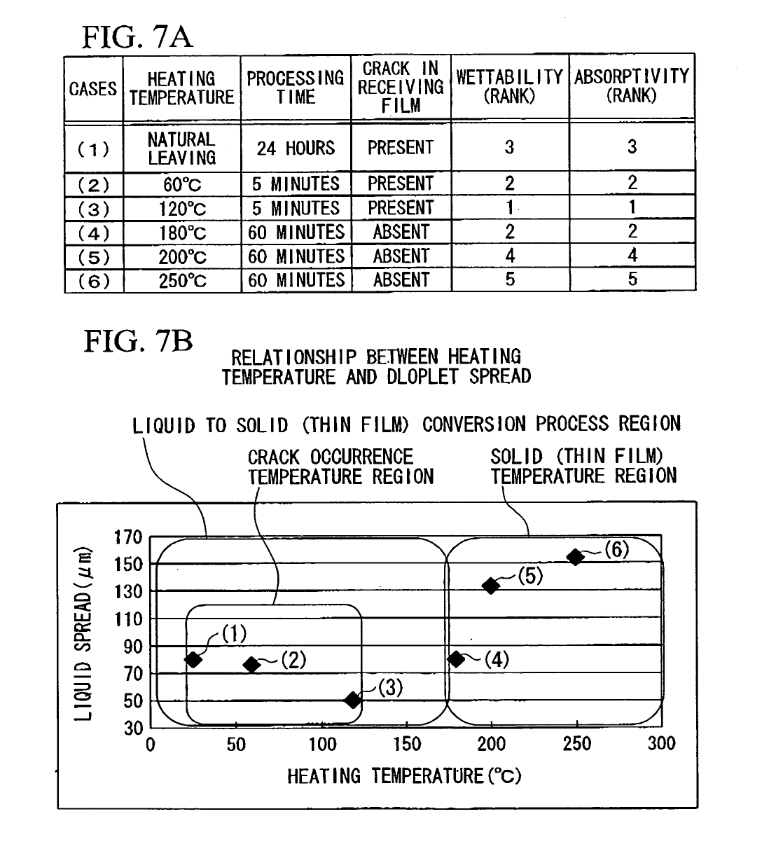

FIGS. 7A and 7B show the results of the experiments. FIG. 7A is a table showing the results of the experiments. FIG. 7B is a graph of FIG. 7A.

As indicated in FIGS. 7A and 7B, when the functional fluid LQ2 was placed on the receiving films 36 formed under the conditions (1) to (4), the receiving films 36 were cracked. For the wettability of the receiving film 36 with the functional fluid LQ2 obtained when the functional fluid LQ2 was placed on the receiving films 36 formed under the conditions (1) to (6), the value obtained was highest under the condition (3) and decreased in order of the conditions (4), (2), (1), and (5). The wettability was lowest under the condition (6). For the absorptivity of the receiving film 36 to the functional fluid LQ2 obtained when the functional fluid LQ2 was placed on the receiving films 36 formed under the conditions (1) to (6), the value obtained was largest under the condition (3) and decreased in order of the conditions (4), (2), (1), and (5). The absorptivity was lowest under the condition (6). The “droplet spread” on the axis of ordinate in FIG. 7(b) indicates the amount of wetting and spreading observed when a droplet of the functional fluid LQ2 of a predetermined diameter was placed on the receiving film 36. The value for the droplet spread decreases with increasing absorptivity of the receiving film 36. On the basis of the present experiment results, the condition (4) can be determined to the optimum drying condition taking into account conditions under which no cracks occur.

### (EXPERIMENTAL EXAMPLE 2)

Porous silica was used as a material used to form a receiving film 36. Further, an organic silver compound was used as a material used to form a wiring pattern 33. A droplet of a functional fluid containing porous silica was ejected from the droplet ejecting head 1 to the groove portion 34. Then, a thermal treatment was executed at about 300° C. for about 60 minutes. Conditions for the ejection of the droplet of the functional fluid containing the porous silica included a droplet amount of 4 pL and a droplet flying speed of 5 to 7 m/sec. Thus, a receiving film 36 consisting of the porous silica was formed in the groove portion 34. Then, a droplet of a functional fluid containing the organic silver compound was ejected from the droplet ejecting head 1 onto the receiving film 36. Then, a thermal treatment was executed at about 200° C. for about 60 minutes. It was thus possible to form a wiring pattern 33 in the groove portion 34.

(Method for Forming Wiring Pattern (Second Embodiment))

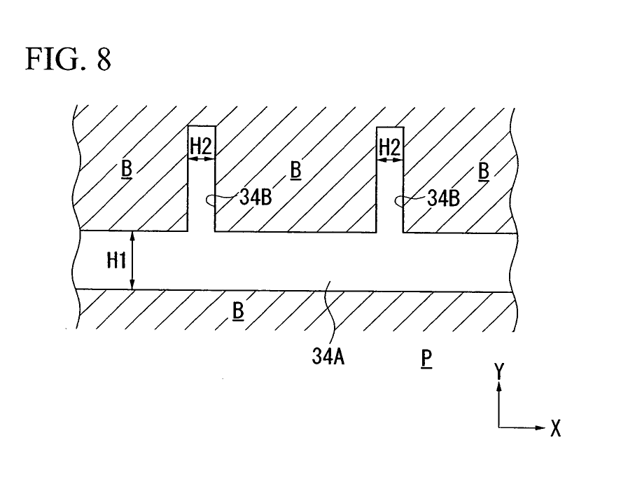

Now, with reference to FIG. 8, a description will be given of a method for forming a wiring pattern according to the present invention. FIG. 8 is a schematic diagram illustrating the method for forming a wiring pattern according to the present embodiment. In the description below, components that are the same as or equivalent to corresponding ones of the above embodiment are denoted by the same reference numerals. The description of these components is simplified or omitted.

As shown in FIG. 8, a first groove portion 34A and a second groove portion 34B are formed by the banks B on the substrate P; the first groove portion 34A has a first width H1 and the second groove portion 34B has a second width H2 so as to connect to the first groove portion 34A. The second width H2 is smaller than the first width H1. Further, in FIG. 8, the first groove portion 34A is extended in an X axis direction, whereas the second groove portion 34B is extended in a Y axis direction different from the X axis direction.

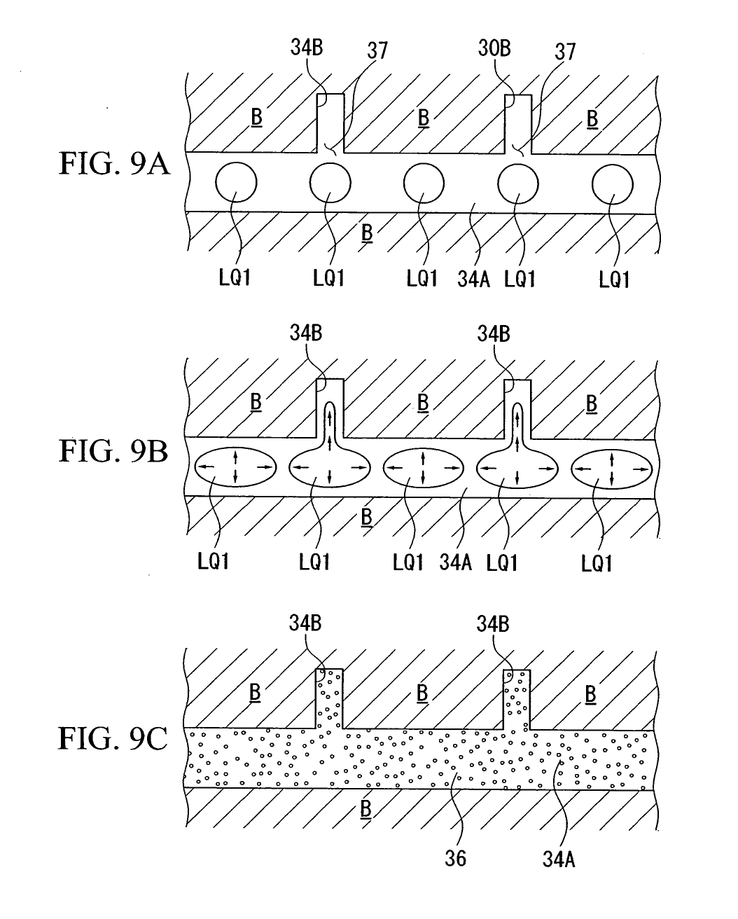

To form a receiving film 36 in the groove portions 34A and 34B, the droplet ejecting head 1 is first used to place droplets of the functional fluid LQ1 used to form a receiving film 36, at predetermined positions in the first groove portion 34A, as shown in FIG. 9A. According to the present embodiment, porous silica is used as a receiving film forming material. To arrange droplets of the functional fluid LQ1 in the first groove portion 34A, the droplet ejecting head 1 set above the first groove portion 34A is used to eject the droplets to the first groove portion 34A. According to the present embodiment, as shown in FIG. 9A, the droplets of the functional fluid LQ1 are arranged at predetermined intervals along a longitudinal direction (X axis direction) of the first groove portion 34A. In this case, the droplets of the functional fluid LQ1 are also arranged near connecting portions 37 of the first groove portion 34A at which the first groove portion 34A and the second groove portion 34B are connected together.

As shown in FIG. 9B, the functional fluid LQ1 placed in the first groove portion 34A spreads in the first groove portion 34A while wetting it, as a result of self-flowage. Moreover, the functional fluid LQ1 placed in the first groove portion 34A also spreads in the second groove portion 34B while wetting it, as a result of the self-flowage. It is thus possible to place the functional fluid LQ1 in the second groove portion 34B without the need to eject the functional fluid LQ1 directly to the second groove portion 34B from above it.

By thus placing the functional fluid LQ1 in the first groove portion 34A, it is possible to place the functional fluid LQ1 in the second groove portion 34B as a result of the self-flowage (capillary phenomenon) of the functional fluid LQ1 placed in the first groove portion 34A. Therefore, it is possible to smoothly place the functional fluid LQ1 in the second groove portion 34B by ejecting the functional fluid LQ1 in the first groove portion 34A, having the large width H1, and without the need to eject the functional fluid LQ1 to the second groove portion 34B, having the small width H2, from above the banks B. In particular, even if the width H2 of the second groove portion 34B is small and the diameter of droplets ejected from the droplet ejecting head 1 (the diameter of flying droplets) is smaller than the width H2, the self-flowage of the functional fluid LQ1 enables the functional fluid LQ1 to be smoothly placed in the second groove portion 34B. The small width of the second groove portion 34B allows the functional fluid LQ1 to be smoothly placed in the second groove portion 34B as a result of the capillary phenomenon. Therefore, a film pattern with a desired shape can be formed. Since the functional fluid LQ1 can be smoothly placed in the second groove portion 34B, having the small width, the film pattern can be formed of thin lines (a fine film pattern can be formed). On the other hand, even though the functional fluid LQ1 is ejected to the first groove portion 34A from above the banks B, the large width H1 of the first groove portion 34A makes it possible to avoid the disadvantage of splashing the functional fluid Q1 on the top surfaces 38 of the banks B to form residues.

Further, according to the present embodiment, even if it is difficult to place the functional fluid LQ1 in the second groove portion 34B from above the banks B, the functional fluid LQ1 can be smoothly placed in the second groove portion 34B.

After the functional fluid LQ1 has been placed in the first groove portion 34A and the second groove portion 34B, a drying process is executed under predetermined conditions as in the case of the first embodiment to convert the functional fluid LQ1 into the receiving film 36 as shown in FIG. 9C. When the drying condition is, for example, heating at about 300° C. for about 60 minutes, a receiving film 36 consisting of a porous member (porous silica) can be formed.

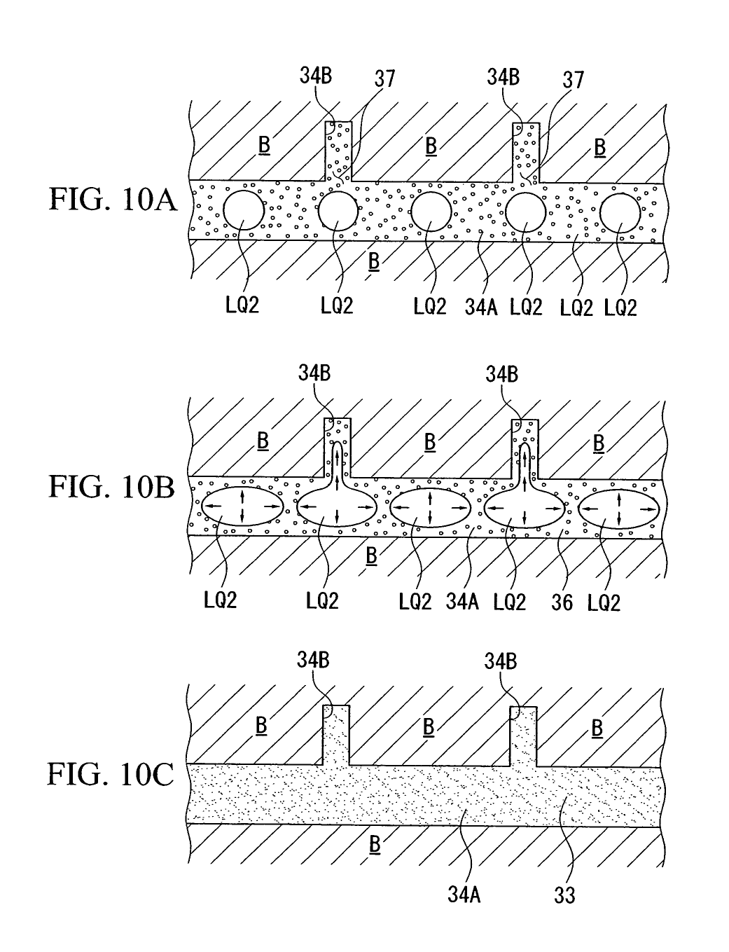

After the receiving film 36 has been formed, the droplet ejecting head 1 is used to place droplets of the functional fluid LQ2 used to form a wiring pattern 33, at predetermined positions in the first groove portion 34A, as shown in FIG. 10A. According to the present embodiment, the organic silver compound is used as a wiring pattern forming material.

To arrange droplets of the functional fluid LQ2 in the first groove portion 34A, the droplet ejecting head 1 set above the first groove portion 34A is used to eject the droplets to the first groove portion 34A. According to the present embodiment, as shown in FIG. 10A, the droplets of the functional fluid LQ2 are arranged at predetermined intervals along the longitudinal direction (X axis direction) of the first groove portion 34A. In this case, the droplets of the functional fluid LQ2 are also arranged near the connecting portions 37 of the first groove portion 34A at which the first groove portion 34A and the second groove portion 34B are connected together.

As shown in FIG. 10B, the functional fluid LQ2 placed in the first groove portion 34A spreads in the first groove portion 34A while wetting it, as a result of self-flowage. Moreover, the functional fluid LQ2 placed in the first groove portion 34A also spreads in the second groove portion 34B while wetting it, as a result of the self-flowage. It is thus possible to place the functional fluid LQ2 in the second groove portion 34B without the need to eject the functional fluid LQ2 directly to the second groove portion 34B from above it.

By thus placing the functional fluid LQ2 in the first groove portion 34A in which the receiving film 36 is provided, it is possible to place the functional fluid LQ2 in the second groove portion 34B as a result of the self-flowage (capillary phenomenon) of the functional fluid LQ2 placed in the first groove portion 34A. Therefore, it is possible to smoothly place the functional fluid LQ2 in the second groove portion 34B by ejecting the functional fluid LQ2 in the first groove portion 34A, having the large width H1, and without the need to eject the functional fluid LQ2 to the second groove portion 34B, having the small width H2, from above the banks B. In particular, even if the width H2 of the second groove portion 34B is small and the diameter of droplets ejected from the droplet ejecting head 1 (the diameter of flying droplets) is smaller than the width H2, the self-flowage of the functional fluid LQ2 enables the functional fluid LQ2 to be smoothly placed in the second groove portion 34B. The small width H2 of the second groove portion 34B allows the functional fluid LQ2 to be smoothly placed in the second groove portion 34B as a result of the capillary phenomenon. Therefore, a wiring pattern 33 with a desired shape can be formed. Since the functional fluid LQ2 can be smoothly placed in the second groove portion 34B, having the small width, the wiring pattern 33 can be formed of thin lines (a fine film pattern can be formed). On the other hand, even though the functional fluid LQ2 is ejected to the first groove portion 34A from above the banks B, the large width H1 of the first groove portion 34A makes it possible to avoid the disadvantage of splashing the functional fluid Q2 on the top surfaces 38 of the banks B to form residues. It is thus possible to prevent the disadvantage of generating a leak current.

Further, according to the present embodiment, even if it is difficult to place the functional fluid LQ2 in the second groove portion 34B from above the banks B, the functional fluid LQ2 can be smoothly placed in the second groove portion 34B.

After the functional fluid LQ2 has been placed in the first groove portion 34A and the second groove portion 34B, a baking process is executed under predetermined conditions as in the case of the first embodiment to convert the functional fluid LQ2 into the wiring pattern 33 as shown in FIG. 10C. When the baking condition is, for example, heating at 200° C. for about 60 minutes, the wiring pattern 33 can be formed.

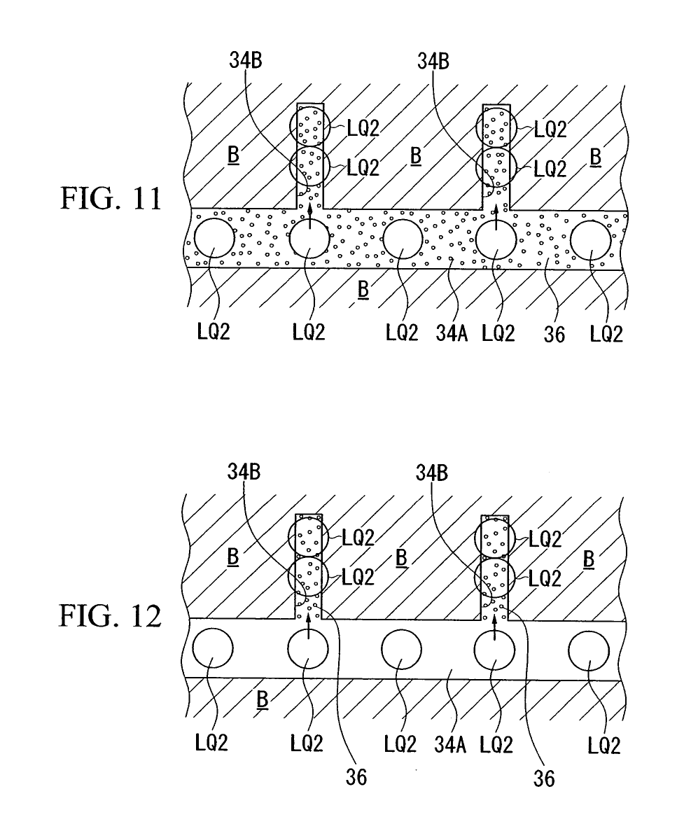

As shown in FIG. 11, it is possible to provide the receiving film 36 in the first groove portion 34A and second groove portion 34B and then eject droplets of the functional fluid LQ2 containing the wiring pattern forming material, to the second groove portion 34B from above it. Thus, the second groove portion 34B is filled with the functional fluid LQ2 ejected to the first groove portion 34A and flowing into the second groove portion 34B as a result of the self-flowage and droplets of the functional fluid LQ2 ejected (supplied) directly to the second groove portion 34B from above it. In this case, the small width H2 of the second groove portion 34B may cause the droplets of the functional fluid LQ2 to splash on the top surfaces 38 of the banks B. Since the second groove portion 34B is provided with the receiving film 36, the droplets of the functional fluid LQ2 ejected area drawn into the second groove portion 34B. This avoids the disadvantage of leaving residues on the top surfaces of the banks B.

In the embodiment shown in FIG. 11, if the second groove portion 34B is filled with the functional fluid LQ2, it may be filled only with droplets of the functional fluid LQ ejected (supplied) directly to the second groove portion 34B from above it.

If the second groove portion 34B is filled only with droplets of the functional fluid LQ2 ejected (supplied) directly to the second groove portion 34B from above it, the receiving film 36 may be provided only in the second groove portion 34B, having the small width H2 as shown in FIG. 12. The functional fluid LQ2 ejected directly to the second groove portion 34B is drawn by the receiving film 36 into the second groove portion 34B. This makes it possible to avoid the disadvantage of leaving residues on the top surfaces 38 of the banks B. On the other hand, because of the large width H1 of the first groove portion 34A, the functional fluid LQ2 can be smoothly placed in the first groove portion 34A in spite of the absence of the receiving film 36 and without leaving residues on the top surfaces 38 of the banks B.

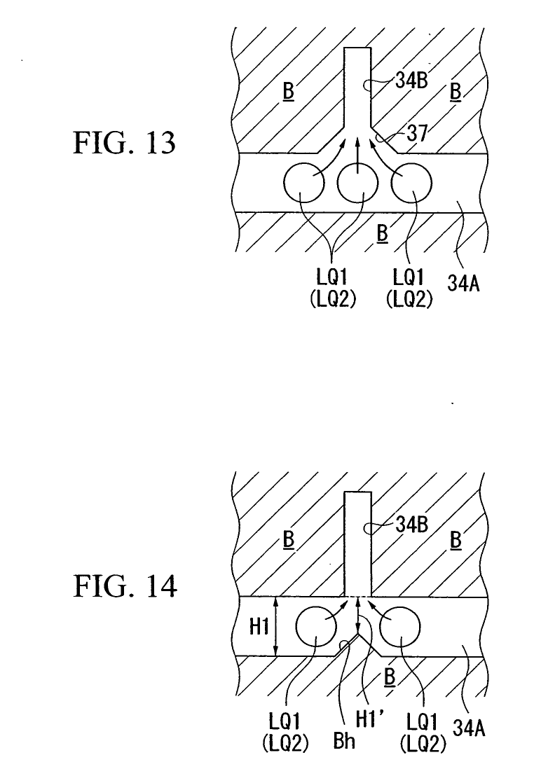

As shown in FIG. 13, the connecting portion 37 between the first groove portion 34A and the second groove portion 34B may be tapered from the first groove portion 34A toward the second groove portion 34B. This enables the functional fluid LQ1 (LQ2) placed in the first groove portion 34A to flow smoothly into the second groove portion 34B.

Further, as shown in FIG. 14, when the direction in which the first groove portion 34A is extended crosses the direction in which the second groove portion 34B is extended, the width H1′ of an area of the first groove portion 34A which is close to the second groove portion 34B may be locally smaller than the width H1 of the other areas. This enables the functional fluid LQ1 (LQ2) placed in the first groove portion 34A to flow smoothly into the second groove portion 34B. In this case, when an inner wall surface Bh of the bank B forming the first groove portion 34A inclines toward the second groove portion 34B, the functional fluid LQ1 (LQ2) placed in the first groove portion 34A can be caused to flow more smoothly into the second groove portion 34B.

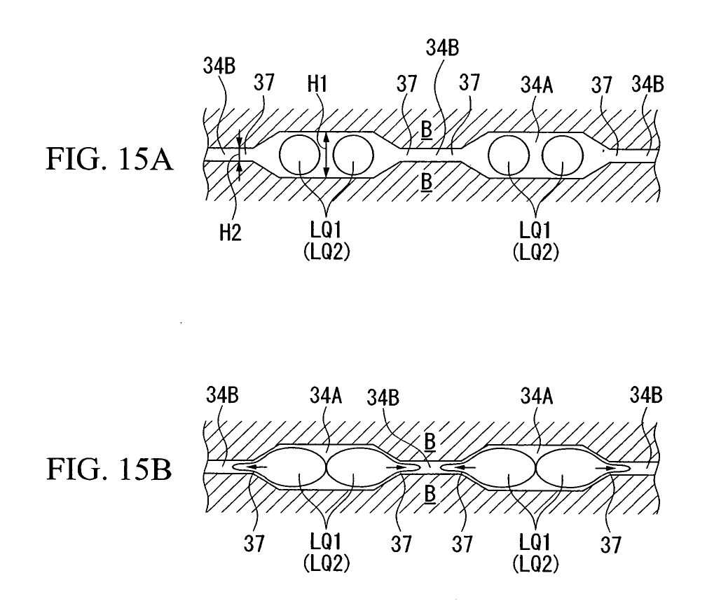

In the above embodiments, the extending direction of the first groove portion 34A, having the large width H1, is different from that of the second groove portion 34B, having the small width H2. However, as shown in FIGS. 15A and 15B, the extending direction of the first groove portion 34A, having the large width H1, may be the same as that of the second groove portion 34B, having the small width H2. In this case, as shown in FIG. 15A, when the functional fluid LQ1 (LQ2) is placed in the first groove portion 34A, the functional fluid LQ1 (LQ2) can also be placed in the second groove portion 34B as a result of its self-flowage. Also in this case, by tapering the connecting portion 37 between the first groove portion 34A and the second groove portion 34B from the first groove portion 34A toward the second groove portion 34B, it is possible to cause the functional fluid LQ1 (LQ2) placed in the first groove portion 34A to flow smoothly into the second groove portion 34B.

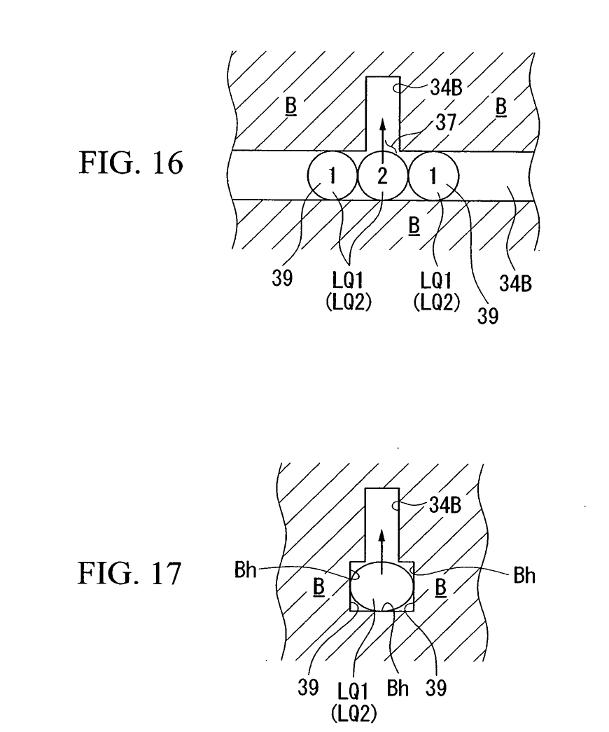

Furthermore, when the functional fluid LQ1 (LQ2) placed in the first groove portion 34A is transferred to the second groove portion 34B as a result of its self-flowage, dike portions 39 are desirably provided in the areas of the first groove portion 34A other than the connecting portion 37 in which the first groove portion 34A and the second groove portion 34B are connected together, as shown in FIG. 16. The dike portions 39 in FIG. 16 are droplets of the functional fluid LQ1 (LQ2) placed in the first groove portion 34A.

The droplets of the functional fluid LQ1 (LQ2) used as the dike portions 39 are not caused to flow into the second groove portion 34B but are initially placed in the first groove portion 34A. In FIG. 16, reference numeral “1” denotes the droplets which are initially placed to function as the dike portions 39. The functional fluid LQ1 (LQ2) transferred to the second groove portion 34B as a result of its self-flowage is placed between the connecting portion 37 and the dike portions 39. This droplet is denoted by reference numeral “2”. This inhibits the droplet “2” of the functional fluid LQ1 (LQ2) placed in the area of the first groove portion 34A between the connecting portion 37 and the dike portions 39 (droplet “1 ”) from flowing in the directions other than one toward the connecting portion 37. The droplet “2” thus flows toward the connecting portion 37. Therefore, the droplet “2” flows smoothly into the second groove portion 34B via the connecting portion 37.

Further, as shown in FIG. 17, the inner wall surfaces Bh of the banks B may be used as the dike portions 39.

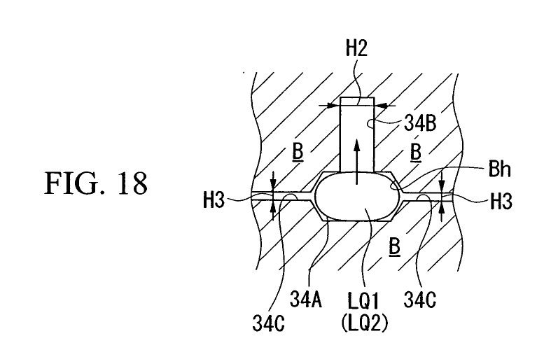

Furthermore, as shown in FIG. 18, even if the first groove portion 34A connects to a third groove portion 34C having a width H3 smaller than both the width HI of the first groove portion 34A and the width H2 of the second groove portion 34B, the functional fluid LQ1 (LQ2) placed in the first groove portion 34A flows smoothly into the second groove portion 34B and third groove portion 34C because the inner wall surfaces Bh of the banks B function as the dike portions 39.

(Thin Film Transistor)

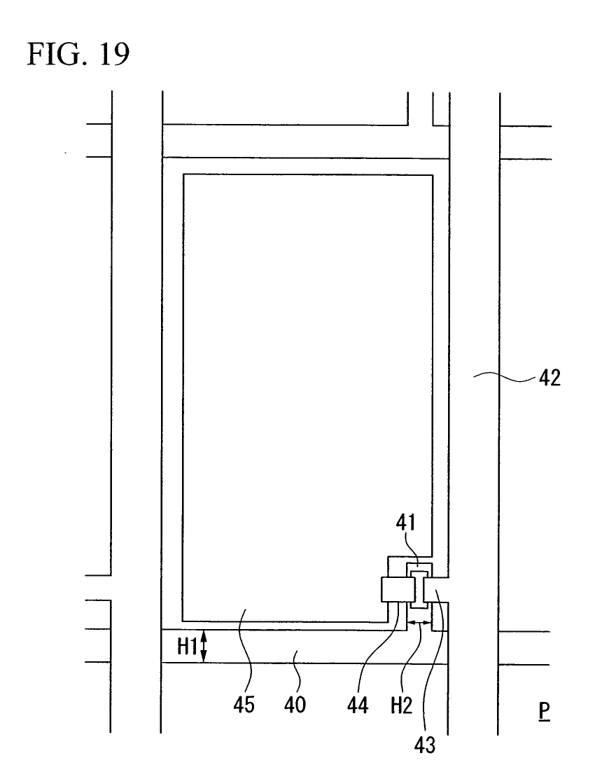

The method for forming a wiring pattern according to the present invention is applicable to the formation of a thin film transistor (TFT) serving as a switching element and wiring connected to the thin film transistor (TFT) as shown in FIG. 19. In FIG. 19, the following components are provided on a TFT substrate P having a TFT: a gate wire 40, a gate electrode 41 electrically connected to the gate wire 40, a source wire 42, a source electrode 43 electrically connected to the source wire 42, a drain electrode 44, and a pixel electrode 45 electrically connected to the drain electrode 44. The gate wire 40 is extended in the X axis direction. The gate electrode 41 is extended in the Y axis direction. The width H2 of the gate electrode 41 is smaller than the width H1 of the gate wire 40. The gate wires 40 and 41 can be formed by the method for forming a wiring pattern according to the present invention.

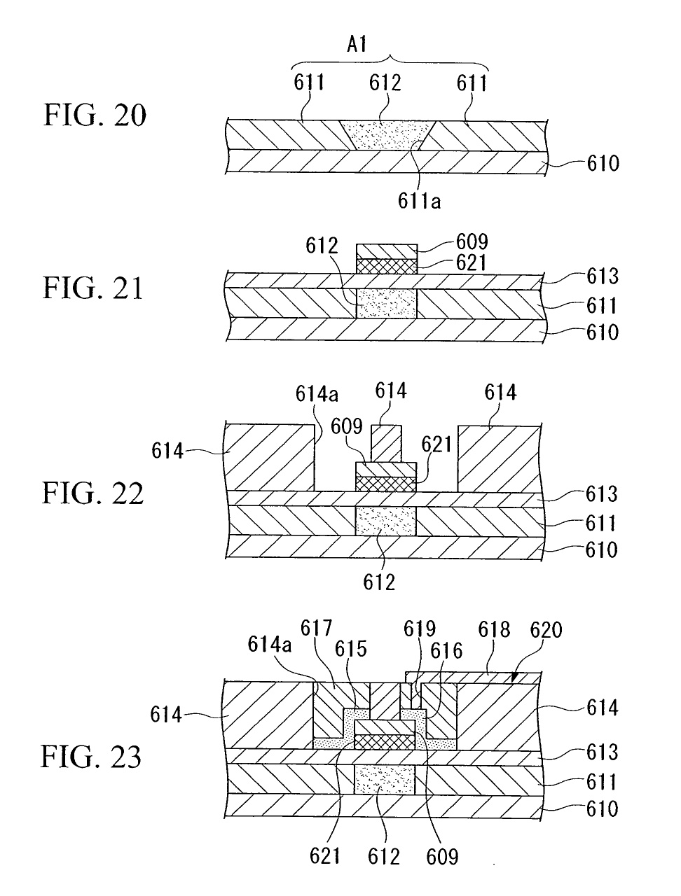

According to the above embodiment, the gate wire of the TFT (Thin Film Transistor) is formed using the method for forming a film pattern according to the present invention. However, this method can also be used to manufacture other components such as the source electrode, the drain electrode, and the pixel electrode. With reference to FIGS. 20 to 23, description will be given of a method for manufacturing a TFT.

As shown in FIG. 20, first layer banks 611 are formed on a top surface of a cleaned glass substrate 610 by the photolithography process; the first layer banks 611 are used to form a groove 611a that is sized one-twentieth to one-tenth of one pixel pitch. The banks formed 611 must exhibit light transmissibility and fluid repellence. A preferable material for the banks 611 is a polymer material such as an acrylic resin, a polyimide resin, an olefin resin, or a melamine resin.

To provide the banks formed 611 with fluid repellence, it is necessary to execute a CF₄ plasma process or the like (a plasma process using a gas containing a fluorine component). However, a fluid-repellent component (a fluorine group or the like) may be filled into the material of the banks 611. In this case, the CF₄ plasma process or the like can be omitted.

The angle of contact, with ejected ink, of the banks 611 made fluid-repellent as described above is preferably at least 40°. Further, the contact angle of a glass surface is preferably at most 10°. The results of the inventors' experiments show that for example, a treatment of fine conductive grains (a tetradecane solvent) ensures a contact angle of about 54.0° if an acrylic resin is employed as a material of the banks 611 (the contact angle is at most 10° if the fine conductive grains are untreated). These values of the contact angle were obtained when a tetrafluoromethane gas was supplied at a rate of 0.1 L/min using a plasma power of 550 W.

In a gate scan electrode forming step (first conductive pattern forming step) following the first-layer bank forming step, a gate scan electrode 612 is formed by using ink jet to eject droplets containing a conductive material so that the groove 611a, which is a drawn area partitioned by the banks 611, is filled with the droplets. The method for forming a pattern according to the present invention is applied to the formation of the gate scan electrode 612.

The conductive material is suitably Ag, Al, Au, Cu, palladium, Ni, W—Si, a conductive polymer, or the like. Since the banks 611 are provided with a sufficient fluid repellence, the gate scan electrode thus formed 612 can form a fine wiring pattern that does not protrude from the groove 611a.

The above steps form, on the substrate 610, a first conductive layer A1 consisting of the banks 611 and the gate scan electrode 612 and provided with a flat top surface.

To allow droplets to be appropriately ejected to the groove 611a as shown in FIG. 20, it is preferable to employ a quasi-taper for the shape of the groove 611a (the groove 611a fans out toward the ejection source). This makes it possible to transfer ejected droplets sufficiently deep into the groove 611a.

Then, as shown in FIG. 21, a plasma CVD process is used to consecutively form a gate insulating film 613, an active layer 621, and a contact layer 609. A nitrogenized silicon layer is formed as the gate insulating film 613. An amorphous silicon film is formed as the active layer 621. An n⁺ silicon film is formed as the contact layer 609 by varying a material gas and plasma conditions. If a CVD process is used, a heat history of 300 to 350° C. is required. However, problems concerning transparency and heat insulation can be avoided by using an inorganic material for the banks.

In a second-layer bank forming step following the semiconductor layer forming step as shown in FIG. 22, second layer banks 614 are formed on a top surface of the gate insulating film 613 on the basis of the photolithography process; the second layer banks 614 are used to form a groove 614a which is sized one-twentieth to one-tenth of one pixel pitch and which crosses the groove 611a. The banks formed 614 must exhibit light transmissibility and fluid repellence. A preferable material for the banks 614 is a polymer material such as an acrylic resin, a polyimide resin, an olefin resin, or a melamine resin.

To provide the banks formed 614 with fluid repellence, it is necessary to execute a CF₄ plasma process or the like (a plasma process using a gas containing a fluorine component). However, a fluid-repellent component (a fluorine group or the like) may be filled into the material of the banks 614. In this case, the CF₄ plasma process or the like can be omitted.

The angle of contact, with ejected ink, of the banks 614 made fluid-repellent as described above is preferably at least 40°.

In a source and drain electrode forming step (second conductive pattern forming step) following the second-layer bank forming step, a source electrode 615 and a drain electrode 616 crossing the gate scan electrode 612 is formed by using ink jet to eject droplets containing a conductive material so that the groove 614a, which is a drawn area partitioned by the banks, is filled with the droplets. The method for forming a pattern according to the present invention is applied to the formation of the source electrode 615 and the drain electrode 616.

The conductive material is suitably Ag, Al, Au, Cu, palladium, Ni, W—Si, a conductive polymer, or the like. Since the banks 614 are provided with a sufficient fluid repellence, the source electrode 615 and drain electrode 616 thus formed can form a fine wiring pattern that does not protrude from the groove 614a.

Further, an insulating material 617 is placed so as to bury the groove 614a in which the source electrode 615 and the drain electrode 616 are arranged. The above steps form a flat top surface 620 consisting of the bank 614 and the insulating material 617, on the substrate 610.

Then, a contact hole 619 is formed in the insulating material 617. A patterned pixel electrode (ITO) 618 is formed on a top surface 620 of the insulating material 617. The drain electrode 616 and the pixel electrode 618 are connected together via the contact hole 619 to form a TFT.

(Electro-optical apparatus)

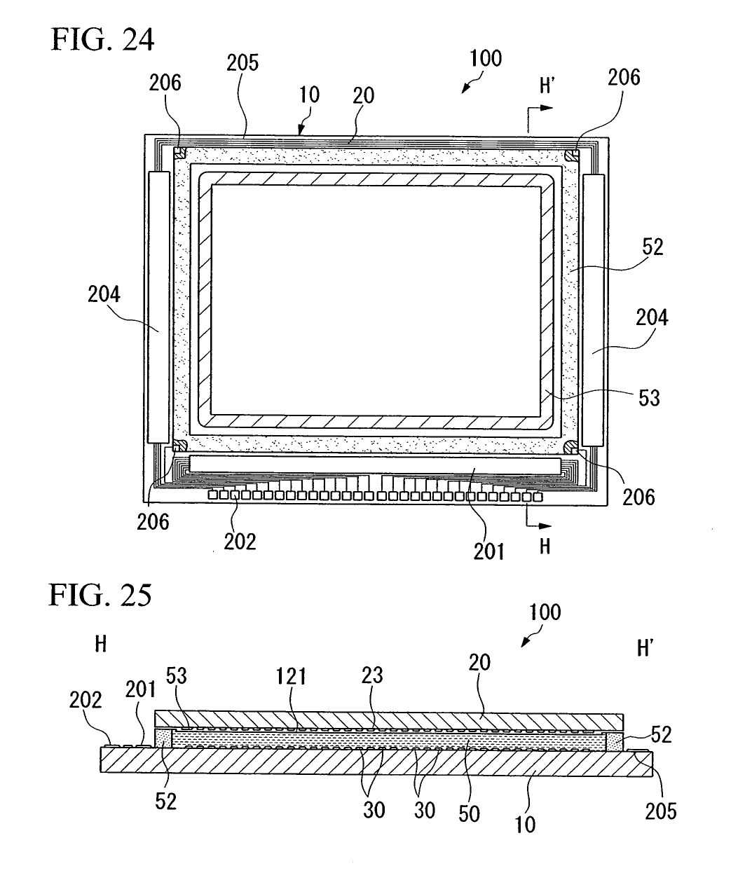

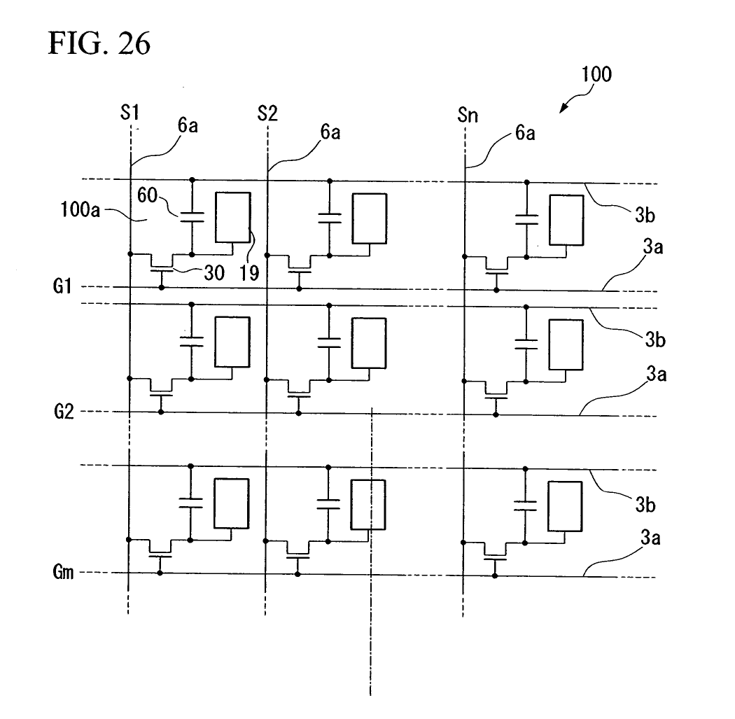

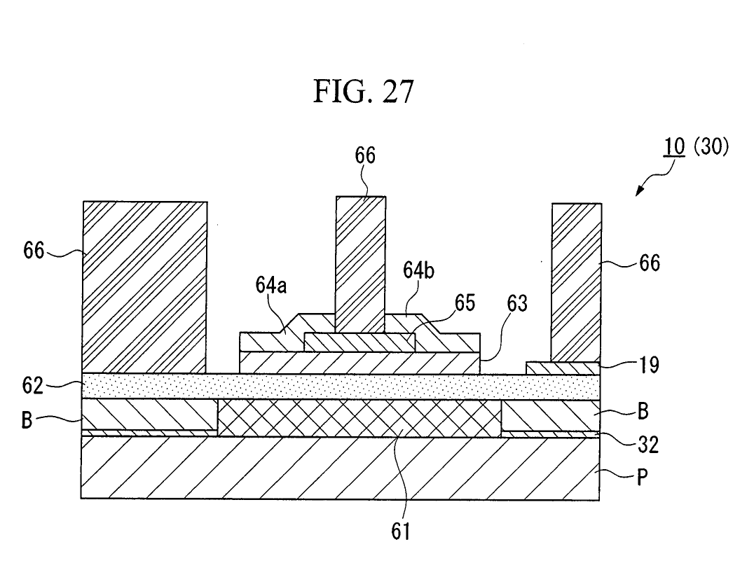

A description will be given of a liquid crystal display device that is an example of an electro-optical apparatus according to the present invention. FIG. 24 is a plan view showing the liquid crystal display device according to the present invention together with its components, as viewed from an opposite substrate. FIG. 25 is a sectional view taken along line H-H′ in FIG. 24. FIG. 26 is an equivalent circuit diagram of elements, wires, and the line in a plurality of pixels formed in a matrix in an image display area of the liquid crystal display device. FIG. 27 is a partly enlarged sectional view of the liquid crystal display device. In the figures used for the description below, layers and members are not shown to scale so that they have sizes that can be seen on the drawings.

In FIGS. 24 and 25, the liquid crystal display device (electro-optical apparatus) 100 according to the present embodiment comprises a TFT array substrate 10 and an opposite substrate 20 which constitute a pair and which are laminated together using a photo-setting seal material 52. A liquid crystal 50 is sealed and held in an area partitioned by the seal material 52. The seal material 52 is formed like a closed frame in an area within a substrate surface.

A peripheral parting line 53 consisting of a light blocking material is formed in an area inside the area in which the seal material 52 is formed. A data line driving circuit 201 and a packaged terminal 202 are formed along a side of the TFT array substrate 10. Scan line driving circuits 204 are formed along two sides adjacent to the side along which the data line driving circuit 201 and the mounted terminal 202 are formed. A plurality of wires 205 are provided on the remaining one side of the TFT array substrate 10 to connect the scan line driving circuits 204, provided on the opposite sides of an image display area. Further, an inter-substrate conducting material 206 is disposed in at least one of the corners of the opposite substrate 20 to electrically connect the TFT array substrate 10 and the opposite substrate 20 together.

Instead of forming the data line driving circuit 201 and the scan line driving circuits 204 on the TFT array substrate 10, it is possible to, for example, electrically and mechanically connect a TAB (Tape Automated Bonding) substrate on which a driving LSI is mounted and a group of terminals formed in a peripheral portion of the TFT array substrate 10, together via an anisotropic conductive film. In the liquid crystal display device 100, a phase difference plate, a polarizing plate, and the like are arranged in predetermined orientations depending on the type of the liquid crystal 50 used, that is, an operation mode such as a TN (Twisted Nematic) mode or an STN (Super Twisted Nematic) mode, or whether the liquid crystal is in a normally white mode or a normally black mode. However, this is not shown in the drawings. Further, if the liquid crystal display device 100 is adapted for color display, then for example, a red (R), green (G), and blue (B) color filters with their protective films are formed in an area of the opposite substrate 20 which is opposite pixel electrodes of the TFT array substrate 10, which will be described later.

In the image display area of the liquid crystal display device 100 having such a structure, as shown in FIG. 26, a plurality of pixels 100a are constructed in a matrix. A TFT for pixel switching (switching element) 30 is formed in each of the pixels 100a. A data line 6a is electrically connected to sources of the TFTs 30 to supply pixel signals S1, S2, . . . Sn to the TFTs 30. The pixel signals S1, S2, . . . Sn, written to the data line 6a, may be sequentially supplied to the respective data lines 6a in this order or may be supplied to every group of a plurality of adjacent data lines 6a. Further, a scan line 3a is electrically connected to gates of the TFT 30. Predetermined timings are used to sequentially and pulsatively apply scan signals G1, G2, . . . Gm to the respective scan lines 3a in this order.

A pixel electrode 19 is electrically connected to a drain of the TFT 30. When the TFT 30, a switching element, is kept on for a specified period, the pixel electrode 19 writes the pixel signal S1, S2, . . . Sn supplied by the data line 6a, to the corresponding pixel in accordance with a predetermined timing. The pixel signals S1, S2, . . . Sn thus written to the liquid crystal via the pixel electrodes 19 and having a predetermined level are held between the pixel electrodes 19 and opposite electrodes 121 of the opposite substrate 20, shown in FIG. 25, for a specified period. To prevent leakage from the pixel signals S1, S2, . . . Sn held, an accumulative capacitance 60 is provided in parallel with a liquid crystal capacitance formed between the pixel electrodes 19 and the opposite electrodes 121. For example, the voltage of the pixel electrode 19 is held by the accumulative capacitance 60 for a time longer than that for which a source voltage has been applied, by three orders of magnitude. This improves a charge holding characteristic to provide a liquid crystal display device 100 with a high contrast ratio.

FIG. 27 is a partly enlarged sectional view of the liquid crystal display device 100 having the bottom gate type TFT 30. The glass substrate P, constituting the TFT array substrate 10, has a gate wire 61 formed between the banks B and B on the glass substrate P by the method for forming a wiring pattern according to the embodiment.

A semiconductor layer 63 consisting of an amorphous silicon (a-Si) layer is stacked on the gate wire 61 via a gate insulating film 62 consisting of SiNx. A part of the semiconductor layer 63 which is opposite the gate wire portion constitutes a channel area. Joining layers 64a and 64b consisting of, for example, an n⁺ type a-Si layer are stacked on the semiconductor layer 63 in order to obtain an Ohmic junction. An insulating etch stop film 65 consisting of SiNx is formed on the semiconductor layer 63 in a central portion of the channel area in order to protect a channel. The gate insulating film 62, the semiconductor layer 63, and the etch stop film 65 are patterned as shown in the figure, by carrying out resist application, exposure, development, and photo etching after deposition (CVD).

Moreover, the joining layers 64a and 64b and the pixel electrode 19, which consists of ITO, are formed and then patterned by photo etching as shown in the figure. Then, banks 66, . . . are projected from the pixel electrode 19, gate insulating film 62, and etch stop film 65. The above droplet ejecting apparatus IJ is then used to eject droplets of a silver compound to between the banks 66 . . . to form a source line and a drain line.

In the above embodiment, the TFT 30 is used as a switching element for driving the liquid crystal display device 100. However, the present invention is applicable to, for example, an organic EL (Electro Luminescence) display device in addition to the liquid crystal display device. The organic EL display device comprises a film including a fluorescent inorganic and organic compounds and sandwiched between a cathode and an anode. Electrons and holes are injected into the film to excite the film to generate excitons. Then, the excitons are recoupled together to emit light (fluorescence or phosphorescence).

A spontaneous-light full-color EL device can be manufactured on the substrate having the TFT 30, by using, as ink, a material that emits a red, green, or blue lights, that is, a light emitting layer forming material, and a material that forms a hole injection/electron transportation layer, and patterning the ink. The scope of the device (electro-optical apparatus) according to the present invention includes such an organic EL device.

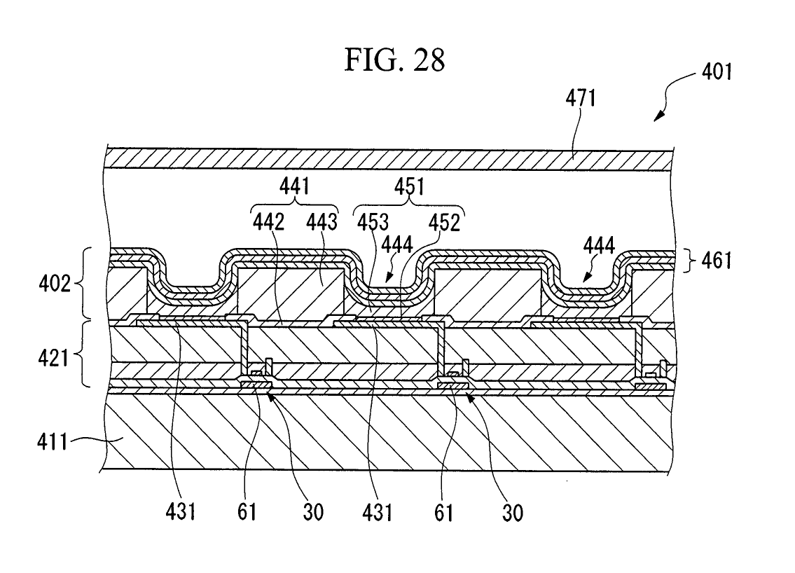

FIG. 28 is a side sectional view of an organic EL device in which some components are manufactured using the droplet ejecting apparatus IJ. The configuration of the organic EL device will be described with reference to FIG. 28.

In FIG. 28, an organic EL device 401 comprises an organic EL element 402 composed of a substrate 411, a circuit element portion 421, a pixel electrode 431, a bank portion 441, a light emitting element 451, a cathode 461 (opposite electrode), and a sealing substrate 471. The organic EL element 402 is connected to wiring and a driving IC (not shown) in a flexible circuit (not shown). The circuit element portion 421 comprises the TFT 60 formed on the substrate 411 and serving as an active element. A plurality of pixel electrodes 431 are aligned with one another on the circuit element portion 421. The gate wire 61, which constitutes the TFT 60, is formed using the method for forming a wiring pattern according to the above embodiment.

Bank portions 441 are formed between the pixel electrodes 431 in lattice form. A light emitting element 451 is formed in a concave opening 444 formed by the bank portions 441. The light emitting element 451 consists of an element that emits a red light, an element that emits a green light, and an element that emits a blue light. This allows the organic EL device 401 to realize full color display. The cathode 461 is formed all over the top surfaces of the bank portion 441 and light emitting element 451. A sealing substrate 471 is stacked on the cathode 461.

A process of manufacturing an organic EL device 401 including an organic EL element includes a bank portion forming step of forming bank portions 441, a plasma processing step executed to allow the appropriate formation of a light emitting element 451, a light emitting element forming step of forming a light emitting element 451, an opposite electrode forming step of forming a cathode 461, and a sealing step of stacking the sealing substrate 471 on the cathode 461 for sealing.

The light emitting element forming step forms a hole ejection layer 452 and a light emitting layer 453 on the concave opening 444, that is, on the pixel electrode 431, to form a light emitting element 451. The light emitting element forming step includes a hole injection layer forming step and a light emitting layer forming step. The hole injection layer forming step has a first ejecting step of ejecting an aqueous material used to form a hole injection layer 452, onto each pixel electrode 431, and a first drying step of drying the ejected aqueous material to form a hole injection layer 452. Further, the light emitting layer forming step has a second ejecting step of ejecting an aqueous material used to form a light emitting layer 453, onto the hole injection layer 452, and a second drying step of drying the ejected aqueous material to form a light emitting layer 453. Three types of light emitting layers 453 are formed using materials corresponding to the three colors red, green, and blue. Accordingly, the second ejecting step consists of three steps in order to eject the three types of materials.

In the light element forming step, the above droplet ejecting apparatus IJ can be used for the first ejecting step of the hole injection layer forming step and for the second ejecting step of the light emitting layer forming step.

The device (electro-optical apparatus) to which the present invention is applicable includes not only the one described above but also, for example, a PDP (Plasma Display Panel) or a surface conduction type electron emitting element that utilizes a phenomenon in which when a current is passed through a small-area thin film formed on the substrate so that the current flows parallel with the surface, electrons are emitted.

Now, description will be given of an example in which a film pattern formed by the method of forming a film pattern according to the present invention is applied to a plasma type display device.

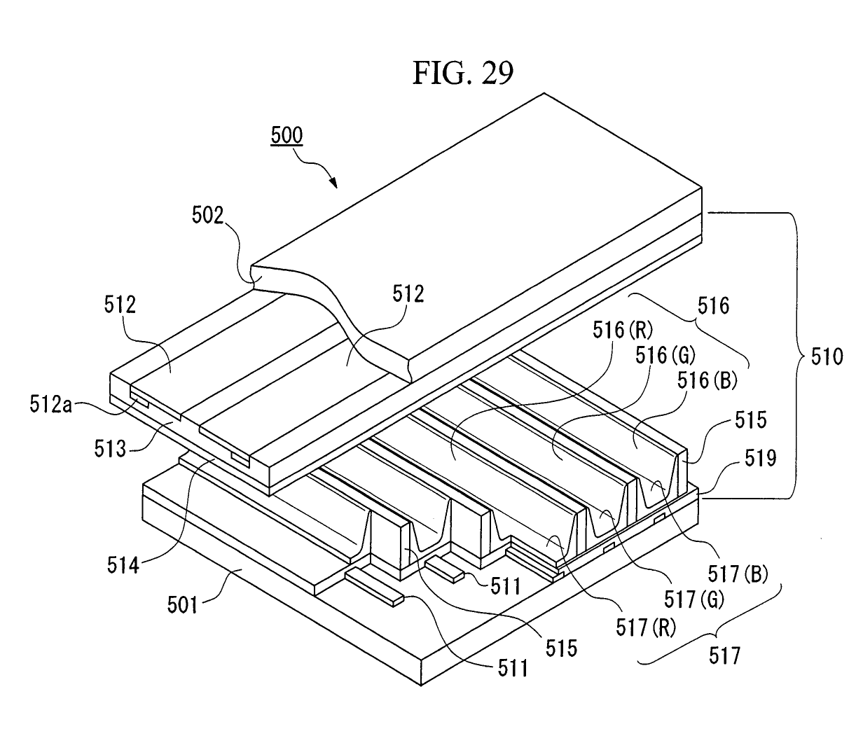

FIG. 29 is an exploded perspective view of a plasma type display device 500 according to the present embodiment.

The plasma type display device 500 includes substrates 501 and 502 arranged opposite each other and a discharge display section 510 formed between the substrates 501 and 502.

The discharge display section 510 is a set of a plurality of discharge chambers 516. Of the plurality of discharge chambers 516, three discharge chambers 516 including a red discharge chamber 516(R), a green discharge chamber 516(G), and a blue discharge chamber 516(B) constitute a set and thus one pixel.

Address electrodes 511 are formed on a top surface of the substrate 501 at predetermined intervals in stripe form. A dielectric layer 519 is formed so as to cover top surfaces of the address electrodes 511 and substrate 501.

Partition walls 515 are each formed on the dielectric layer 519 between and along the address electrodes 511 and 511. The partition walls 515 include those located on laterally opposite sides of each address electrode 511 in a width direction and those extended in a direction orthogonal to the address electrodes 511. Further, each of the discharge chambers 516 is formed in association with a rectangular area enclosed by the partition walls 515.

A phosphor 517 is placed inside the rectangular area enclosed by the partition walls 515. The phosphor 517 emits one of a red, green, and blue fluorescences. A red phosphor 517(R) is placed at a bottom portion of the red discharge chamber 516(R). A green phosphor 517(G) is placed at a bottom portion of the green discharge chamber 516(G). A blue phosphor 517(B) is placed at a bottom portion of the blue discharge chamber 516(B).

On the other hand, a plurality of display electrodes 512 are formed on the substrate 512 at predetermined intervals in stripe form in a direction orthogonal to the address electrodes 511. Moreover, a dielectric layer 513 and a protective film 514 consisting of MgO are formed so as to cover the display electrodes 512.

The substrates 501 and 502 are stuck together so that the address electrodes 511 and the display electrodes 512 cross at right angles.

The address electrodes 511 and the display electrodes 512 are connected to an AC power source (not shown). A current is passed through the electrodes to excite the phosphors 517 of the discharge display section 510. The phosphors 517 thus emit fluorescence to enable color display.

According to the present embodiment, the address electrodes 511 and the display electrodes 512 are formed on the basis of the method for forming a wiring pattern. This serves to achieve a reduction in size and thickness. It is also possible to provide a high-quality plasma type display apparatus that does not undergo any defects such as an open circuit.

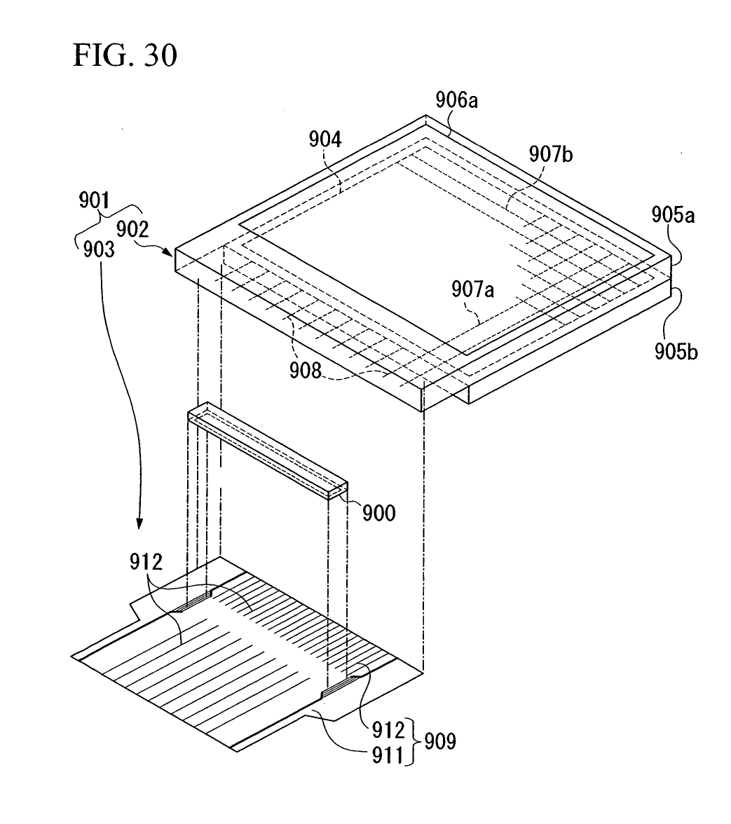

FIG. 30 is a diagram showing another embodiment of a liquid crystal display apparatus.

A liquid crystal display apparatus (electro-optical apparatus) 901 shown in FIG. 30 roughly includes a color liquid crystal panel (electro-optic panel) 902 and a circuit substrate 903 connected to the liquid crystal panel 902. Further, the liquid crystal panel 902 is provided with an illuminating device such as a backlight and other attached devices.

The liquid crystal panel 902 has a pair of substrates 905a and 905b bonded together using a seal material 904. A liquid crystal is sealed in a gap formed between the substrates 905a and 905b, that is, a cell gap. The substrates 905a and 905b are generally formed of a translucent material, for example, glass or a synthetic resin. A polarizing plates 906a and 906b are stuck to outer surfaces of the substrates 905a and 905b, respectively. In FIG. 30, the polarizing plate 906b is omitted.

Further, electrodes 907a are formed on an inner surface of the substrate 905a. Electrodes 907b are formed on an inner surface of the substrate 905b. The electrodes 907a and 907b. are formed like stripes or in a character, number, or other appropriate pattern. The electrodes 907a and 907b are formed of a translucent material, for example, ITO (Indium Tin Oxide). The substrate 905a has an extended portion extended from the substrate 905b. A plurality of terminals 908 are formed in the extended portion. The terminals 908 are formed simultaneously with the formation of electrodes 907a on the substrate 905a. Accordingly, the terminals 908 are formed of, for example, ITO. Some of the terminals 908 extend integrally from the electrodes 907a, while others are connected to the electrodes 907b via conductive materials (not shown).

A semiconductor element 900 serving as a liquid crystal driving IC is mounted on a wiring substrate 909 at a predetermined position. Although not shown, resistors, capacitors, or other chip parts may be mounted at predetermined positions in the areas other than the one in which the semiconductor element 900 is mounted. The wiring substrate 909 is manufactured by patterning a metal film such as Cu formed on a flexible base substrate 911 such as polyimide to form a wiring pattern 912.

According to the present embodiment, the above method for manufacturing a device is used to form electrodes 907a and 907b on the liquid crystal panel 902 and a wiring pattern 912 on the circuit substrate 903.

The present embodiment makes it possible to provide a high-quality liquid crystal display apparatus having uniform electrical characteristics.

The passive liquid crystal panel has been described by way of example. However, the present invention is applicable to an active matrix type liquid crystal. Specifically, thin film transistors (TFTs) are formed on one of two substrates. Pixel electrodes are formed on the respective pixel electrodes. Further, wiring (gate and source wires) electrically connected to the TFTs can be formed using the ink jet technique as described above. On the other hand, opposite electrodes and the like are formed on the opposite electrode. The present invention is applicable to such an active matrix type liquid crystal panel.

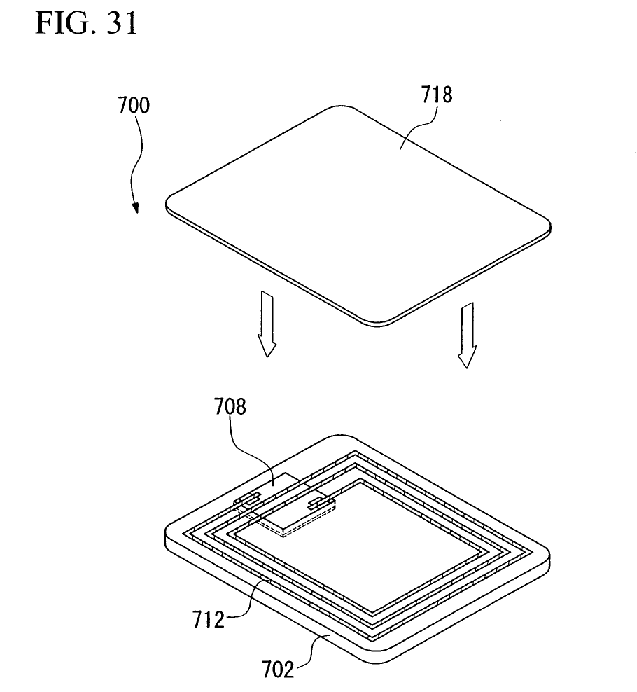

Description will be given of a non-contact type card medium that is another embodiment. As shown in FIG. 31, a non-contact type card medium (electronic apparatus) 700 includes a housing which consists of a card base 702 and a card cover 718 and into which a semiconductor integrated circuit chip 708 and an antenna circuit 712 are built. The non-contact type card medium 700 uses at least one of electromagnetic waves and capacitive coupling to supply power to or receive data from an external transceiver (not shown). According to the present embodiment, the antenna circuit 712 is formed using the method for forming a wiring pattern according to the above embodiment.

The apparatus (electro-optical apparatus) to which the present invention is applicable includes not only the one described above but also, for example, a PDP (Plasma Display Panel) or a surface conduction type electron emitting element that utilizes a phenomenon in which when a current is passed through a small-area thin film formed on the substrate so that the current flows parallel with the surface of the film, electrons are emitted.

(Electronic Apparatus)

Description will be given of a specific example of an electronic apparatus according to the present invention.

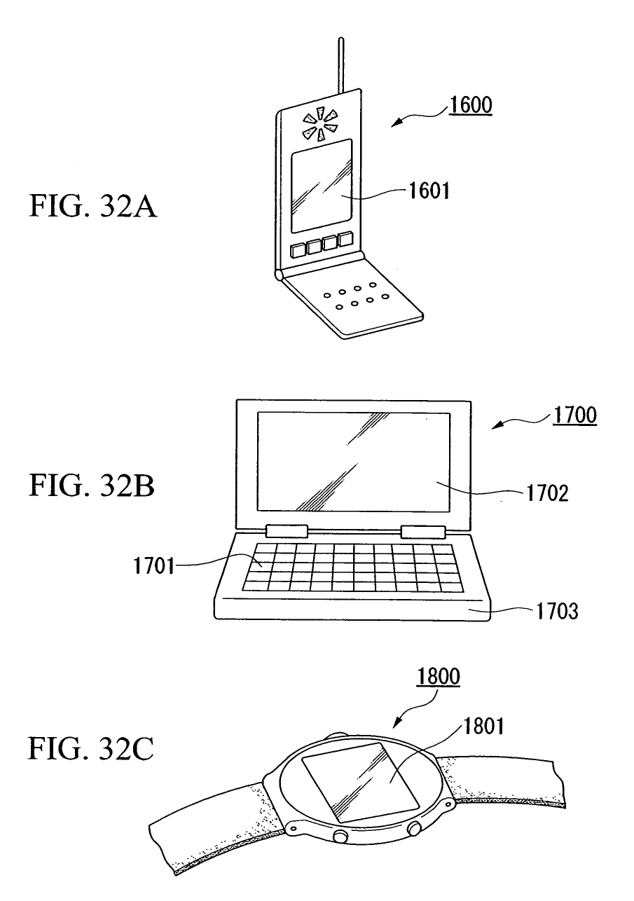

FIG. 32A is a perspective view showing an example of a cellular phone. In FIG. 32A, reference numeral 1600 denotes a cellular phone main body. Reference numeral 1601 denotes a liquid crystal display section includes the liquid crystal display device according to the above embodiment.

FIG. 32B is a perspective view showing an example of a portable information processing apparatus such as a word processor or a personal computer. In FIG. 32B, reference numerals 1700 and 1701 denote an information processing apparatus and an input section such as a keyboard, respectively. Reference numerals 1703 and 1702 denote an information processing main body and a liquid crystal display section comprising the liquid crystal display device according to the above embodiment.

FIG. 32C is a perspective view showing an example of a watch type electronic apparatus. In FIG. 32C, reference numeral 1800 denotes a watch main body. Reference numeral 1801 denotes a liquid crystal display section includes the liquid crystal display device according to the above embodiment.

The electronic apparatus shown in FIGS. 32(a) to 32(c) comprises the liquid crystal display apparatus according to the above embodiment. The electronic apparatus has a wiring pattern of a desired film thickness.

According to the present embodiment, the electronic apparatus includes the liquid crystal. However, the electronic apparatus includes another electro-optical apparatus such as an organic electroluminescence display device or a plasma type display apparatus.

The examples of the preferred embodiment of the present invention have been described with reference to the accompanying drawings. However, of course, the present invention is not limited these examples. The shapes, combinations, and the like of the components shown above in the examples are only examples. Various changes may be made to these examples without departing from the sprit of the present invention.

Further, according to the above embodiments, the thin film pattern is a conductive film. However, the present invention is not limited to this. For example, the present invention is applicable to, for example, a color filter used in a liquid crystal display device to display images in color. The color filter can be formed arranging droplets of an R (red), G (green), and B (blue) inks on a substrate in a predetermined pattern. However, by forming banks corresponding to the predetermined pattern on the substrate, providing the banks with fluid repellence, and then arranging the inks to form a color filter, it is possible to manufacture a liquid crystal display device having a high-performance color filter.

1. A method for forming a film pattern by placing a functional fluid on a substrate, the method comprising:
forming banks having a predetermined pattern on the substrate;
providing a receiving film comprising a porous member, in a groove between the banks; and
placing the functional fluid on the receiving film.

2. A method for forming a film pattern according to claim 1,
wherein the proving the receiving film includes:
placing a second functional fluid in the groove; and
executing a predetermined process on the second functional fluid placed in the groove to convert the second functional fluid into the receiving film.

3. A method for forming a film pattern according to claim 2, wherein the predetermined process includes a thermal treatment of the second functional fluid placed in the groove, and the thermal treatment is used to form a receiving film comprising a porous member.

4. A method for forming a film pattern according to claim 2, wherein the placing the second functional fluid uses a liquid ejecting method.

5. A method for forming a film pattern according to claim 2,
wherein on the substrate, the banks are used to form a first groove having a first width and a second groove is formed which is connected to the first groove and which has a second width, and
the second functional fluid is placed in the first groove, and self-flowage of the second functional fluid placed in the first groove places the second functional fluid in the second groove.

6. A method for forming a film pattern according to claim 5, wherein the second width is equal to or smaller than the first width.

7. A method for forming a film pattern according to claim 5, wherein the functional fluid is placed in the first groove, and self-flowage of the functional fluid placed in the first groove places the functional fluid in the second groove.

8. A method for forming a film pattern according to claim 2,
wherein on the substrate, the banks are used to form a first groove extending in a first direction and a second groove is formed which is connected to the first groove and which extends in a second direction, and
the second functional fluid is placed in the first groove, and self-flowage of the second functional fluid placed in the first groove places the second functional fluid in the second groove.

9. A method for forming a film pattern according to claim 8, wherein the functional fluid is placed in the first groove, and self-flowage of the functional fluid placed in the first groove places the functional fluid in the second groove.

10. A method for forming a film pattern according to claim 1, wherein the functional fluid contains fine conductive grains.

11. A method for forming a film pattern according to claim 1, wherein the functional fluid contains a material that develops conductivity when subjected to a thermal or optical treatment.

12. A method for forming a film pattern according to claim 2, wherein the functional fluid and the second functional fluid are substantially the same.

13. A method for forming a film pattern according to claim 2, wherein the functional fluid and the second functional fluid are different.

14. A method for forming a film pattern according to claim 1, wherein the placing the functional fluid uses a liquid ejecting method.

15. A method for manufacturing a device, the method comprising forming a film pattern on a substrate,
wherein the film pattern is formed on the substrate using the method for forming a film pattern according to claim 1.

16. An electro-optical apparatus comprising a device manufactured using the method for manufacturing a device according to claim 15.

17. An electronic apparatus comprising the electro-optical apparatus according to claim 16.

18. A method for forming a film pattern by placing a first functional fluid on a substrate, the method comprising:
forming banks having a predetermined pattern on the substrate;
placing a second functional fluid in a first groove formed by the banks and placing the second functional fluid in a second groove connected to the first groove as a result of self-flowage of the second functional fluid placed in the first fluid;
executing a predetermined process on the second functional fluid placed in the first and second grooves to convert the second functional fluid into a film; and
placing the first functional fluid on the film.

19. A method for forming a film pattern according to claim 18, wherein the predetermined process includes converting the second functional fluid placed in the first and second grooves into a receiving film having receptivity to the first functional fluid.

20. A method for forming a film pattern according to claim 18, wherein a dike portion is provided at positions of the first groove other than a connecting portion in which the first groove and the second groove are connected together.

21. A method for forming a film pattern according to claim 18, wherein the first groove and the second groove have different widths.

22. A method for forming a film pattern according to claim 21, wherein the width of the second groove is equal to or smaller than that of the first groove.

23. A method for forming a film pattern according to claim 18, wherein the first groove and the second groove are formed to extend in different directions.

24. A method for manufacturing a device, the method comprising forming a film pattern on a substrate,
wherein the film pattern is formed on the substrate using the method for forming a film pattern according to claim 18.

25. An electro-optical apparatus comprising a device manufactured using the method for manufacturing a device according to claim 24.

26. An electronic apparatus comprising the electro-optical apparatus according to claim 25.

27. A method for forming a film pattern by placing a functional fluid on a substrate, the method comprising:
forming banks having a predetermined pattern on the substrate;
providing a first groove formed by the banks and a second groove connected to the first groove and having a smaller width than the first groove and providing a receiving film having receptivity to the functional fluid, in at least the second groove; and
feeding the functional fluid from above the second groove to place the functional fluid in the second groove on which the receiving film is provided.

28. A method for manufacturing a device, the method comprising forming a film pattern on a substrate,
wherein the film pattern is formed on the substrate using the method for forming a film pattern according to claim 27.

29. An electro-optical apparatus comprising a device manufactured using the method for manufacturing a device according to claim 28.

30. An electronic apparatus comprising the electro-optical apparatus according to claim 29.

31. A method for manufacturing an active matrix substrate, the method comprising:
forming gate wiring on a substrate;
forming a gate insulating film on the gate wiring;
stacking a semiconductor layer via the gate insulating film;
forming a source electrode and a drain electrode on the gate insulating layer;
placing an insulating material on the source electrode and the drain electrode; and
forming a pixel electrode electrically connected to the drain electrode, and
wherein at least one of the forming gate wiring, the forming a source electrode and a drain electrode, and the forming a pixel electrode has:
forming banks having a predetermined pattern on the substrate;
providing a receiving film comprising a porous member, in a groove between the banks; and
placing the functional fluid on the receiving film.

32. A method for manufacturing an active matrix substrate, the method comprising:
forming gate wiring on a substrate;
forming a gate insulating film on the gate wiring;
stacking a semiconductor layer via the gate insulating film;
forming a source electrode and a drain electrode on the gate insulating layer;
placing an insulating material on the source electrode and the drain electrode; and
forming a pixel electrode electrically connected to the drain electrode, and
wherein at least one of the forming gate wiring, the forming a source electrode and a drain electrode, and the forming a pixel electrode has:
forming banks having a predetermined pattern on the substrate;
placing a second functional fluid in a first groove formed by the banks and placing the second functional fluid in a second groove connected to the first groove as a result of self-flowage of the second functional fluid placed in the first fluid;
executing a predetermined process on the second functional fluid placed in the first and second grooves to convert the second functional fluid into a film; and
placing the first functional fluid on the film.

33. A method for manufacturing an active matrix substrate, the method comprising:
forming gate wiring on a substrate;
forming a gate insulating film on the gate wiring;
stacking a semiconductor layer via the gate insulating film;
forming a source electrode and a drain electrode on the gate insulating layer;
placing an insulating material on the source electrode and the drain electrode; and
forming a pixel electrode electrically connected to the drain electrode, and
wherein at least one of the forming gate wiring, the forming a source electrode and a drain electrode, and the forming a pixel electrode has:
forming banks having a predetermined pattern on the substrate;
providing a first groove formed by the banks and a second groove connected to the first groove and having a smaller width than the first groove and providing a receiving film having receptivity to the functional fluid, in at least the second groove; and
feeding the functional fluid from above the second groove to place the functional fluid in the second groove on which the receiving film is provided.
